(19) United States
(12) Patent Application Publication
(10) Pub. No.: US 2025/0386505 A1
(43) Pub. Date: Dec. 18, 2025

(54) SEMICONDUCTOR DEVICE AND METHOD FOR MANUFACTURING THE SAME

(71) Applicant: Yangtze Memory Technologies Co., Ltd., Wuhan (CN)

(72) Inventors: Zongliang Huo, Wuhan (CN); Wenbin Zhou, Wuhan (CN); Jing Gao, Wuhan (CN); Sizhe Li, Wuhan (CN); Zhengliang Xia, Wuhan (CN); Wenbo Zhang, Wuhan (CN)

(21) Appl. No.: 19/228,625

(22) Filed: Jun. 4, 2025

Related U.S. Application Data
(60) Provisional application No. 63/661,018, filed on Jun. 17, 2024.

(30) Foreign Application Priority Data
Jul. 19, 2024 (CN) 202410978555.7

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

The present disclosure provides a semiconductor device and a method for manufacturing the same. The semiconductor device includes a first stack structure, a source layer, a second stack structure, and a channel structure stacked sequentially along a first direction, wherein the channel structure extends through the first stack structure, the source layer, and the second stack structure, and is connected to the source layer. In the above-mentioned semiconductor device, the source layer is disposed between the first stack structure and the second stack structure, so that the length of the channel structure to be driven by the source layer is shortened, which is beneficial for improving the current intensity in the channel structure, and improving the problem of weak current intensity in the channel structure caused by increasing the length of the channel structure.

### CROSS-REFERENCE TO RELATED APPLICATIONS

This application claims the benefit of priorities to Chinese Application No. 202410978555.7, filed on Jul. 19, 2024, and U.S. Provisional Application No. 63/661,018, filed on Jun. 17, 2024, both of which are hereby incorporated by reference in their entireties.

### TECHNICAL FIELD

The present disclosure relates to the technical field of semiconductor chips, and in particular to a semiconductor device and a method for manufacturing the same.

### BACKGROUND

As the feature size of a memory cell approaches the lower limit of the process, planar processes and fabrication techniques become challenging and costly, which causes the storage density of 2D or planar NAND flash memory to approach the upper limit.

To overcome the limitations imposed by 2D or planar NAND flash memory, a memory having a three-dimensional structure (3D NAND) has been developed in the industry to improve memory density by disposing memory cells three-dimensionally over a substrate.

However, the length of a channel structure increases as the number of stacked layers of 3D NAND increases, while the current density in the channel structure decreases as the length of the channel structure increases.

### SUMMARY

According to one aspect of the present disclosure, a semiconductor device is provided. The semiconductor device may include a first stack structure, a source layer, and a second stack structure stacked sequentially along a first direction. The semiconductor device may include a channel structure extending through the first stack structure, the source layer, and the second stack structure, and connected to the source layer.

In some implementations, the channel structure may include a channel layer and a functional layer disposed around a portion of the channel layer. In some implementations, the channel layer may extend through the first stack structure, the source layer, and the second stack structure along the first direction. In some implementations, the functional layer may include a first portion extending through the first stack structure and contacting the source layer, and a second portion extending through the second stack structure and contacting the source layer.

In some implementations, the first stack structure may include a first sub-stack structure and a second sub-stack structure stacked along the first direction, and the second sub-stack structure may be between the first sub-stack structure and the source layer.

In some implementations, the semiconductor device may further include a first connection structure extending through the first stack structure, the source layer, and the second stack structure along the first direction, and connected to the source layer.

In some implementations, the semiconductor device may further include a gate isolation structure. In some implementations, the gate isolation structure may extend through the first stack structure, the source layer, and the second stack structure along the first direction and may be located on a side of the channel structure along a second direction, the second direction may intersect with the first direction, and the first connection structure may be disposed around the gate isolation structure.

In some implementations, the first stack structure may include first gate layers and first dielectric layers stacked alternately along the first direction. In some implementations, the second stack structure may include second gate layers and second dielectric layers stacked alternately along the first direction. In some implementations, the semiconductor device may further include a first isolation layer between the first connection structure and the first gate layers, and a second isolation layer between the first connection structure and the second gate layers.

In some implementations, the first stack structure may include first gate layers and first dielectric layers stacked alternately along the first direction. In some implementations, the second stack structure may include second gate layers and second dielectric layers stacked alternately along the first direction. In some implementations, the semiconductor device may further include a second connection structure located on a side of the first stack structure and the second stack structure. In some implementations, the second connection structure may be connected to at least one of the first gate layers, and the second connection structure may be connected to at least one of the second gate layers.

In some implementations, the second connection structure may include a connection pillar extending along the first direction. In some implementations, the second connection structure may include at least one of first connection layers. In some implementations, the first connection layers may be parallel to a second direction, one of the first connection layers connecting the connection pillar and one of the first gate layers, and the second direction may intersect with the first direction. In some implementations, the second connection structure may include at least one of second connection layers, the second connection layers may be parallel to the second direction, one of the second connection layers may connect the connection pillar and one of the second gate layers.

In some implementations, the connection pillar, the first connection layers, and the second connection layers may be in an integral structure.

In some implementations, the semiconductor device may further include a third stack structure abutting the first stack structure along a third direction, and may include third and fourth dielectric layers stacked alternately along the first direction. In some implementations, the third direction may intersect with the plane where the first and second directions are located. In some implementations, the semiconductor device may further include a fourth stack structure stacked with the third stack structure along the first direction, and may include fifth and sixth dielectric layers stacked alternately along the first direction. In some implementations, the connection pillar may extend through the third stack structure and the fourth stack structure, at least one of the third dielectric layers may be connected to at least one of the first connection layers, and at least one of the fifth dielectric layers may be connected to at least one of the second connection layers.

In some implementations, the source layer may be between the third stack structure and the fourth stack structure, and the connection pillar may extend through the source layer. In some implementations, the semiconductor device may further a third isolation layer disposed around the connection pillar and located between the connection pillar and the source layer.

In some implementations, the semiconductor device may further include a first bit line extending in a direction intersecting with the first direction and located on a side of the first stack structure away from the second stack structure. In some implementations, the first bit line may be connected to the channel structure. In some implementations, the semiconductor device may further include a second bit line extending in a direction intersecting with the first direction and located on a side of the second stack structure away from the first stack structure. In some implementations, the second bit line may be connected to the channel structure. In some implementations, the first bit line may be connected to the second bit line.

In some implementations, the semiconductor device may further include a third connection structure extending through the first stack structure, the source layer, and the second stack structure. In some implementations, the third connection structure may be connected to the first bit line and to the second bit line.

According to another aspect of the present disclosure, a method of manufacturing a semiconductor device is provided. The method may include forming a first layer-stacked structure. A first region of the first layer-stacked structure may include multiple first sacrificial layers and multiple first dielectric layers stacked alternately along a first direction, and the first region of the first layer-stacked structure may abut a second region of the first layer-stacked structure. The method may include forming a second sacrificial layer stacked with the first layer-stacked structure along the first direction. The method may include forming a second layer-stacked structure located on a side of the second sacrificial layer away from the first layer-stacked structure. A first region of the second layer-stacked structure may include multiple third sacrificial layers and multiple second dielectric layers stacked alternately along the first direction. The first region of the second layer-stacked structure may abut a second region of the second layer-stacked structure. The method may include forming a channel structure that extends through the first layer-stacked structure, the second sacrificial layer, and the second layer-stacked structure. The method may include replacing the second sacrificial layer with a source layer. The source layer may be connected to the channel structure. The method may include replacing the first sacrificial layer with a first gate layer and replacing the third sacrificial layer with a second gate layer.

In some implementations, after the forming the first layer-stacked structure and before the forming the second sacrificial layer, the method may further include removing a portion of the first layer-stacked structure to form a first channel hole. In some implementations, the first channel hole may extend through the first region of the first layer-stacked structure. In some implementations, after the forming the second layer-stacked structure and before the forming the channel structure, the method may further I include removing a portion of the second layer-stacked structure and a portion of the second sacrificial layer to form a second channel hole. In some implementations, the second channel hole may extend through the first region of the second layer-stacked structure, and may be in communication with the first channel hole, and the first and second channel holes may collectively constitute a channel hole.

In some implementations, the forming the first layer-stacked structure may include forming a first sub-layer-stacked structure. In some implementations, the forming the first layer-stacked structure may include removing a portion of the first sub-layer-stacked structure to form a third channel hole that extends through a first region of the first sub-layer-stacked structure. In some implementations, the forming the first layer-stacked structure may include forming a second sub-layer-stacked structure. In some implementations, the second sub-layer-stacked structure may be stacked with the first sub-layer-stacked structure along the first direction. In some implementations, the forming the second layer-stacked structure may include forming a third sub-layer-stacked structure. In some implementations, the forming the second layer-stacked structure may include removing a portion of the second sub-layer-stacked structure, a portion of the second sacrificial layer, and a portion of the third sub-layer-stacked structure to form a fourth channel hole. In some implementations, the fourth channel hole may be in communication with the third channel hole. In some implementations, the forming the second layer-stacked structure may include forming a fourth sub-layer-stacked structure. In some implementations, the fourth sub-layer-stacked structure may be stacked with the third sub-layer-stacked structure along the first direction. In some implementations, the forming the second layer-stacked structure may include removing a portion of the fourth sub-layer-stacked structure to form a fifth channel hole. In some implementations, the fifth channel hole may be in communication with the fourth channel hole, and the third, fourth, and fifth channel holes collectively constitute a channel hole.

In some implementations, the forming the channel structure may include forming a functional layer and a channel layer sequentially within the channel hole. In some implementations, the functional layer may be disposed around the channel layer. In some implementations, the replacing the second sacrificial layer with the source layer may include removing a portion of the second sacrificial layer to form a first filling space. In some implementations, the first filling space may expose a portion of the functional layer. In some implementations, the replacing the second sacrificial layer with the source layer may include removing a portion of the functional layer by the first filling space, and dividing the functional layer into a first portion and a second portion. In some implementations, the first portion may extend through the first layer-stacked structure, and the second portion extends through the second layer-stacked structure. In some implementations, the replacing the second sacrificial layer with the source layer may include forming the source layer in the first filling space.

In some implementations, the removing the portion of the layer-stacked structure to form the channel hole may further include forming a gate line slit. In some implementations, the gate line slit may be in the first region of the first layer-stacked structure and the first region of the second layer-stacked structure, and may be located on a side of the channel hole along a second direction, and the second direction intersects with the first direction.

In some implementations, the removing the portion of the second sacrificial layer to form the first filling space may include removing the portion of the second sacrificial layer through the gate line slit.

In some implementations, after the replacing the first sacrificial layer with the first gate layer, the method may further include forming an isolation layer, a first connection structure, and a gate isolation structure sequentially within the gate line slit. In some implementations, the first connection structure may be disposed around the gate isolation structure and may be connected to the source layer, the isolation layer may be disposed around the first connection structure, the isolation layer between the first connection structure and the first gate layer may constitute a first isolation layer, and the isolation layer between the first connection structure and the second gate layer may constitute a second isolation layer.

In some implementations, the removing the portion of the layer-stacked structure to form the channel hole may further include forming a connection hole that extends through the second region of the first layer-stacked structure and the second region of the second layer-stacked structure. In some implementations, the second region of the first stack structure may include multiple third dielectric layers and multiple fourth dielectric layers stacked alternately along the first direction, and the second region of the second layer-stacked structure may include multiple fifth dielectric layers and multiple sixth dielectric layers stacked alternately along the first direction. In some implementations, after the forming the isolation layer, the first connection structure, and the gate isolation structure sequentially within the gate line slit, the method may further include removing a portion of the third dielectric layer and the fifth dielectric layer to form a second filling space and a third filling space. In some implementations, the second filling space may expose at least one of the first gate layers, the third filling space may expose at least one of the second gate layers, the second filling space may be in communication with the connection hole, and the third filling space may be in communication with the connection hole. In some implementations, after the forming the isolation layer, the first connection structure, and the gate isolation structure sequentially within the gate line slit, the method may further include filling the connection hole with a conductive material to form a second connection structure.

In some implementations, after forming the second connection structure, the method may further include forming a first bit line. In some implementations, the first bit line may extend in a direction intersecting with the first direction and is located on a side of the first layer-stacked structure away from the second layer-stacked structure, and may connected to the channel structure. In some implementations, after forming the second connection structure, the method may further include forming a second bit line. In some implementations, the second bit line may extend in a direction intersecting with the first direction and may be located on a side of the second layer-stacked structure away from the first layer-stacked structure, and may be connected to the channel structure. In some implementations, after forming the second connection structure, the method may further include connecting the first bit line to the second bit line.

### BRIEF DESCRIPTION OF THE DRAWINGS

In order to more clearly illustrate the technical solutions in the present disclosure, the following will briefly introduce the figures required to be used in some implementations of the present disclosure. Obviously, the figures in the following description are only the figures of some implementations of the present disclosure, and those skilled in the art may also obtain other figures according to these figures. In addition, the figures in the following description may be considered schematics and are not intended to limit the actual dimensions of a product, the actual flow of a method, etc., to which the implementations of the present disclosure are directed.

FIG. 1 is a schematic diagram of a three-dimensional structure of a three-dimensional memory according to some implementations;

FIG. 2 is a cross-sectional view of a three-dimensional memory according to some implementations;

FIG. 3 is a cross-sectional view of a memory cell string of the three-dimensional memory shown in FIG. 1 along the section line A-A′;

FIG. 4 is an equivalent circuit diagram of the memory cell string of FIG. 3;

FIG. 5 is a schematic structural diagram of a semiconductor device according to some implementations;

FIG. 6 is a schematic structural diagram of a semiconductor device according to other implementations;

FIG. 7 is a schematic structural diagram of a semiconductor device according to other implementations;

FIG. 8 is a schematic structural diagram of a semiconductor device in a Y-Z plane according to some implementations;

FIG. 9 is an assembled view of the two sections A-A and B-B in FIG. 8;

FIG. 10 is a schematic structural diagram of a third connection structure according to some implementations;

FIG. 11 to FIG. 14 are schematic structural diagrams of semiconductor devices according to some different implementations;

FIG. 15 is a flowchart of a method of manufacturing a semiconductor device according to some implementations;

FIGS. 16-24 are schematic structural diagrams of a semiconductor device in a manufacturing process according to some implementations;

FIG. 25 is a block diagram of a memory system according to some implementations;

FIG. 26 is a block diagram of a memory system according to other implementations; and

FIG. 27 is a block diagram of an electronic device according to some implementations.

Reference numbers: 10, Three-dimensional memory; 100, Peripheral device; 110, Substrate; 120, Transistor; 130, Peripheral interconnection layer; 200, Semiconductor structure; 290, Array interconnection layer; 400, Memory cell string; 500, Bonding interface; SL, Source layer; 410, Channel structure; 411, Channel layer; 412, Functional layer; 4121, Tunneling layer; 4122, Memory layer; 4123, Barrier layer; 4124, First portion; 4125, Second portion; 300, Semiconductor layer; 600, Semiconductor device; 610, First stack structure; 611, First gate layer; 612, First dielectric layer; 6101, First sub-stack structure; 6102, Second sub-stack structure; 620, Second stack structure; 621, Second gate layer; 622, Second dielectric layer; 6201, Third sub-stack structure; 6202, Fourth sub-stack structure; 630, First connection structure; 631, First isolation layer; 632, Second isolation layer; 633, Isolation layer; 640, Gate isolation structure; 650, Second connection structure; 651, Connection pillar; 652, First connection layer; 653, Second connection layer; 654, Third isolation layer; 655, Fourth isolation layer; 656, Fifth isolation layer; 670, Third stack structure; 671, Third dielectric layer; 672, Fourth dielectric layer; 680, Fourth stack structure; 681, Fifth dielectric layer; 682, Sixth dielectric layer; 101, First region; 102, Second region; 690, Repeated structure; BL-1, First bit line; BL-2, Second bit line; 700, Third connection structure; 710, Substrate; 720, Pad; 730, First layer-stacked structure; 7301, First sub-layer-stacked structure; 7302, Second sub-layer-stacked structure; 731, First sacrificial lay; 740, Second layer-stacked structure; 7401, Third sub-layer-stacked structure; 7402, Fourth sub-layer-stacked structure; 741, Third sacrificial layer; 750, Second sacrificial lay; 751, First filling space; 760, Structural stub; 770, Channel hole; 771, First channel hole; 772, Second channel hole; 773, Third channel hole; 774, Fourth channel hole; 775, Fifth channel hole; 780, Gate line slit; 781, First gate line slit; 782, Second gate line slit; 783, Third gate line slit; 784, Fourth gate line slit; 785, Fifth gate line slit; 791, Connection hole; 792, Second filling space; 793, Third filling space.

### DETAILED DESCRIPTION

The following will provide a clear and complete description of the technical solutions in some implementations of the present disclosure, in connection with the accompanying drawings. Obviously, the described implementations are only a part of the implementations of the present disclosure, and not all of the implementations. Based on the implementations provided in the present disclosure, all other implementations obtained by those skilled in the art are within the scope of the present disclosure.

In the description of the present disclosure, it should be understood that the terms such as “center”, “up”, “down”, “front”, “back”, “left”, “right”, “vertical”, “horizontal”, “top”, “bottom”, “inside”, “outside” and the like indicate an orientation or positional relationship based on the orientation or positional relationship shown in the drawings, merely for convenience in describing the present disclosure and to simplify the description, and do not indicate or imply that the devices or elements referred to must have a particular orientation, be constructed and operated in a particular orientation, and therefore should not be construed as limiting the present disclosure.

Unless otherwise required by the context, the term “including” shall be interpreted throughout the description and claims as open and inclusive, meaning “including, but not limited to”. In the description, the terms such as “one implementation”, “some implementations”, “exemplary implementations”, “exemplarily” or “some examples” and the like are intended to indicate that specific features, structures, materials or characteristics related to the implementation(s) or examples are included in at least one of the implementations or examples of the present disclosure. The illustrating representation of the above terms does not necessarily refer to the same implementation or example. In addition, the specific features, structures, materials, or characteristics described may be included in any one or more implementations or examples in any appropriate manner.

Below, the terms “first” and “second” are only used for the purpose of description and should not be understood as indicating or implying relative importance or implying the number of technical features indicated. Thus, the features limited with “first” and “second” may explicitly or implicitly include one or more of the features. In the description of implementations of the present disclosure, the meaning of “multiple” refers to two or more, unless otherwise specified.

When describing some implementations, expressions such as “coupled” and “connected” and their derivatives may be used. For example, when describing some implementations, the term “connected” may be used to indicate that two or more components have direct physical or electrical contact with each other. For another example, when describing some implementations, the term “coupled” may be used to indicate that two or more components have direct physical or electrical contact. However, the term “coupled” may also refer to two or more components that do not have direct contact with each other but still cooperate or interact with each other. The implementations disclosed herein are not necessarily limited to the present disclosure.

“At least one of A, B, and C” has the same meaning as “at least one of A, B, or C” and includes the following combinations of A, B, and C: only A, only B, only C, a combination of A and B, a combination of A and C, a combination of B and C, and a combination of A, B, and C.

“A and/or B” includes the following three combinations: only A, only B, and a combination of A and B.

The use of “applicable” or “configured to” herein implies an open and inclusive language, which does not exclude devices that are applicable or configured to perform additional tasks or operations.

In addition, the use of “based on” implies openness and inclusiveness, as processes, operations, calculations, or other actions based on one or more of the conditions or values described may be based on additional conditions or values beyond those described in practice.

As used herein, “about”, “roughly”, or “approximately” include a value set forth and an average value within an acceptable deviation range of a specific value, where the acceptable deviation range is determined by those of ordinary skill in the art taking into account the measurement being discussed and the errors associated with the measurement of a specific quantity (e.g., limitations of a measurement system).

In the present disclosure, the meanings of “on”, “above”, and “over” should be interpreted in the broadest way, so that “on” not only means “directly on” something, but also includes the meaning of “on” something with intermediate features or layers in between, and “above” or “over” not only means “above” or “over” something, but also includes the meaning of “above” or “over” something without intermediate features or layers in between (e.g., directly on something).

The present disclosure describes exemplary implementations with reference to cross-sectional and/or plan views as idealized exemplary figures. In the figures, the thickness of layers and regions has been enlarged for clarity. Therefore, it may be contemplated that there may be variations in the shape relative to the figures due to, for example, manufacturing techniques and/or tolerances. Therefore, the exemplary implementations should not be interpreted as limited to the shapes of regions shown in the present disclosure, but rather include shape deviations caused by, for example, manufacturing. For example, etched areas shown as rectangles typically have curved features. Therefore, the areas shown in the figures are essentially schematic, and their shapes are not intended to show the actual shapes of the regions of a device, and are not intended to limit the scope of the exemplary implementations.

As used herein, the term “substrate” refers to a material on which subsequent layers of material may be added. The substrate itself may be patterned. The materials added to the substrate may be patterned or may keep un-patterned. In addition, the substrate may include various semiconductor materials such as silicon, germanium, gallium arsenide, indium phosphide, etc. Alternatively, the substrate may be made of non-conductive materials such as glass, plastic, or sapphire wafers.

As used herein, “parallel”, “vertical”, and “equal” include the situations set forth and situations that are similar to the situations set forth, the range of which is within an acceptable deviation range, where the acceptable deviation range is determined by those of ordinary skill in the art taking into account the measurement being discussed and the errors associated with the measurement of a specific quantity (e.g., limitations of a measurement system). For example, “parallel” includes absolute parallel and approximate parallel, where the acceptable deviation range for approximate parallel may be within 5 degrees. “Vertical” includes absolute vertical and approximate vertical, where the acceptable deviation range for approximate vertical may also be within 5 degrees, for example. “Equal” includes absolute equal and approximate equal, where the difference between the two that may be, for example, equal within the acceptable deviation range for approximate equal is less than or equal to 5% of either.

The term “three-dimensional memory” refers to a semiconductor device formed by an array of memory cell transistor strings (referred to as “memory cell strings” herein, such as NAND memory cell strings) arranged in an array on the main surface of a substrate or a source layer and extending in a direction perpendicular to the substrate or source layer. As used herein, the term “vertical/vertically” means nominally perpendicular to the main surface of the substrate or source layer (e.g., lateral surface).

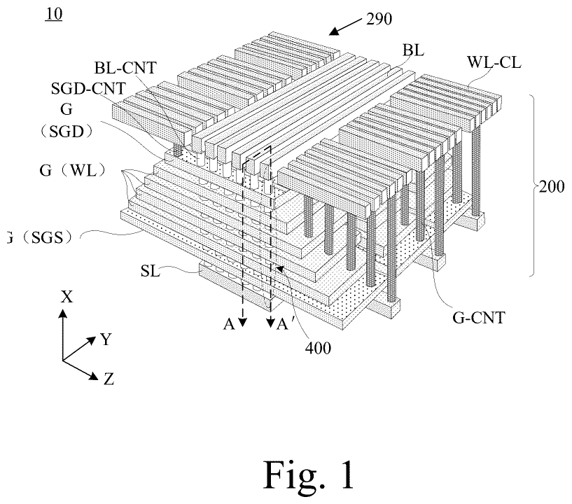

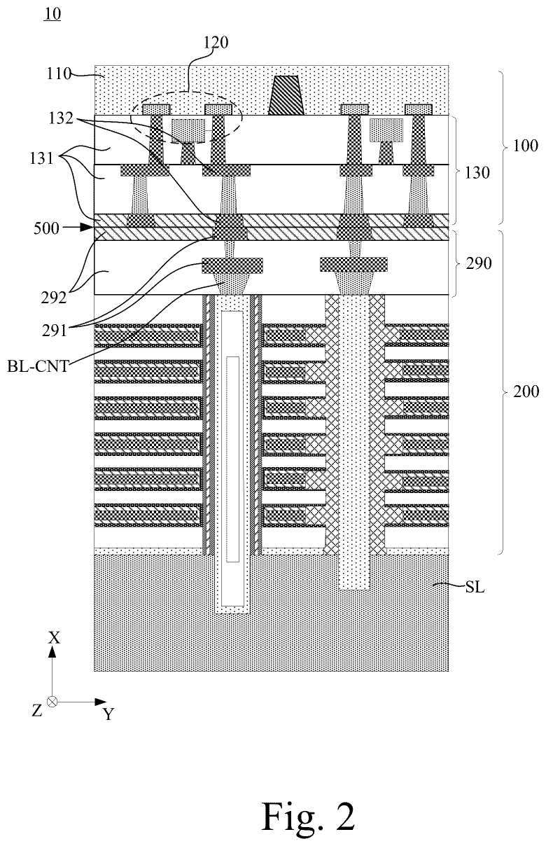

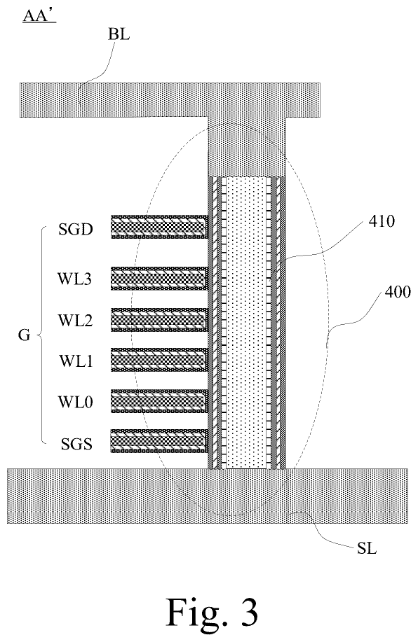

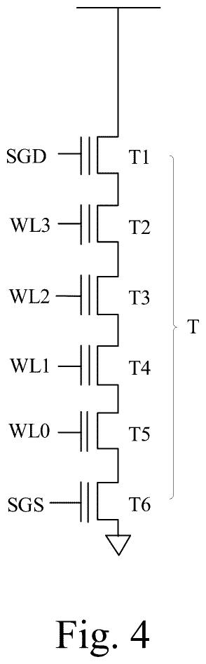

FIG. 1 is a schematic diagram of a three-dimensional structure of a three-dimensional memory according to some implementations. FIG. 2 is a cross-sectional view of a three-dimensional memory according to some implementations. FIG. 3 is a cross-sectional view of a memory cell string of the three-dimensional memory shown in FIG. 1 along the section line AA′. FIG. 4 is an equivalent circuit diagram of the memory cell string of FIG. 3.

Referring to FIGS. 1 and 2, some implementations of the present disclosure provide a three-dimensional memory 10 in the X-Y-Z three-dimensional coordinate system. The three-dimensional memory 10 extends in the Y-Z plane, with the second direction Y, for example, as an extending direction of the bit line BL, and the third direction Z, for example, as an extending direction of the word line WL. The first direction X is perpendicular to the Y-Z plane.

It should be noted that the first direction X intersects with the second direction Y, and the third direction Z intersects with the X-Y plane. The present disclosure only takes the first direction X, the second direction Y, and the third direction Z mutually perpendicular to in pairs as an example, to explain the structures provided in some implementations of the present disclosure.

Referring to FIGS. 1 and 2, some implementations of the present disclosure provide a three-dimensional memory 10. The three-dimensional memory 10 may include a semiconductor structure 200. The three-dimensional memory 10 may also include a source layer SL coupled to the semiconductor structure 200, and a peripheral device 100 coupled to the semiconductor structure 200. The peripheral device 100 may be disposed on a side of the semiconductor structure 200 away from the source layer SL.

The source layer SL may include semiconductor materials such as monocrystalline silicon, monocrystalline germanium, group III-V compound semiconductor materials, group II-VI compound semiconductor materials, and other suitable semiconductor materials. The source layer SL may be partially or completely doped. In an example, the source layer SL may include a doped region doped with a p-type dopant. The source layer SL may also include a non-doped region.

The semiconductor structure 200 may also include memory cell transistor strings arranged in an array (referred to as “memory cell string” herein, such as NAND memory cell string). The source layer SL may be coupled to the source terminals of multiple memory cell strings 400.

In an example, referring to FIGS. 3 and 4, a memory cell string 400 may include multiple transistors T. One transistor T (such as T2-T5 in FIG. 4) may be set as a memory cell. These transistors T are connected together to form the memory cell string 400. A transistor T (e.g., each transistor T) may be formed by a channel structure 410 and a gate line G surrounding the channel structure 410, where the gate line G is configured to control the on state of the transistor.

It should be noted that the number of transistors T in FIGS. 1 to 4 is only illustrative. The memory cell string 400 of the three-dimensional memory 10 provided in an implementation of the present disclosure may also include other numbers of transistors, for example, the number of transistors may be 4, 16, 32, 64, etc.

Furthermore, along the first direction X, the lowermost gate line of the multiple gate lines G (such as the gate line closest to the source layer SL in the multiple gate lines G) is constructed as a source select gate SGS, which is configured to control the on state of the transistor T6 and thus control the on state of the source channel in the memory cell string 400. Along the first direction X, the uppermost gate line of the multiple gate lines G (such as the gate line farthest from the source layer SL in the multiple gate lines G) is constructed as a drain select gate SGD, which is configured to control the on state of the transistor T1 and thus control the on state of the drain channel in the memory cell string 400. The gate line located in the middle among the multiple gate lines G may be constructed as multiple word lines WL, including word lines WL0, WL1, WL2, and WL3, for example. By writing different voltages on a word line WL, data writing, reading, and erasing of each memory cell (such as transistor T) in the memory cell string 400 may be completed.

Still referring to FIGS. 1 and 2, in some implementations, the semiconductor structure 200 may also include an array interconnect layer 290. The array interconnect layer 290 may be coupled to the memory cell string 400. The array interconnect layer 290 may include a drain (e.g., bit line BL) of the memory cell string 400, which may be coupled to a semiconductor channel of each transistor T in at least one memory cell string 400.

The array interconnect layer 290 may include one or more first interlayer insulation layers 292, and may also include multiple contacts insulated from each other by these first interlayer insulation layers 292. The contacts include, for example, a bit line contact BL-CNT, a drain select gate contact SGD-CNT, and a gate line contact G-CNT, where the bit line contact BL-CNT is coupled to the bit line BL, the drain select gate contact SGD-CNT is coupled to the drain select gate SGD, and the gate line contact G-CNT is coupled to the gate line G. The array interconnect layer 290 may also include one or more first interconnect conductive layers 291. The first interconnect conductive layer 291 may include multiple connection lines, such as a bit line BL and a word line connection line WL-CL coupled to the word line WL. The material of the first interconnect conductive layers 291 and the contacts may be a conductive material, such as a combination of one or more of tungsten, cobalt, copper, aluminum, and metal silicides, or other conductive materials. The material of the first interlayer insulating layers 292 is an insulating material, such as a combination of one or more of silicon oxide, silicon nitride, and high dielectric constant insulating materials, or other insulating materials.

The peripheral device 100 may include a peripheral circuit. The peripheral circuit is configured to control and sense array devices. Peripheral circuits may be any suitable digital, analog, or mixed signal control and sensing circuits used to support the operations (or work) of array devices, including but not limited to page buffers, decoders (such as row and column decoders), sense amplifiers, drivers (such as word line drivers), charge pumps, current or voltage references, or any active or passive components of a circuit (such as transistors, diodes, resistors, or capacitors). Peripheral circuits may also include any other circuits compatible with advanced logic processes, including logic circuits such as processors and programmable logic devices (PLDs) or storage circuits such as static random access memory (SRAM).

Specifically, in some implementations, the peripheral device 100 may include a substrate 110, a transistor 120 disposed on the substrate 110, and a peripheral interconnect layer 130 disposed on the substrate 110. The peripheral circuit may include transistor 120.

The material of substrate 110 may be monocrystalline silicon, or other suitable materials such as silicon germanium, germanium, or silicon-on-insulator thin film.

The peripheral interconnect layer 130 is coupled to the transistor 120 to achieve the transmission of electrical signals between the transistor 120 and the peripheral interconnect layer 130. The peripheral interconnect layer 130 may include one or more second interlayer insulating layers 131, and may also include one or more second interconnect conductive layers 132. Different second interconnect conductive layers 132 may be coupled through contacts. The material of the second interconnect conductive layers 132 and the contacts may be a conductive material, such as a combination of one or more of tungsten, cobalt, copper, aluminum, and metal silicides, or other suitable materials. The material of the second interlayer insulating layers 131 is an insulating material, such as a combination of one or more of silicon oxide, silicon nitride, and a high dielectric constant insulating material, or other suitable materials.

The peripheral interconnect layer 130 may be coupled with the array interconnect layer 290, so that the semiconductor structure 200 and the peripheral device 100 are coupled. For instance, due to the coupling between the peripheral interconnect layer 130 and the array interconnect layer 290, the peripheral circuits in the peripheral device 100 may be coupled with the memory cell strings in the semiconductor structure 200 to achieve the transmission of electrical signals between the peripheral circuits and the memory cell strings. In some possible implementations, a bonding interface 500 may be provided between the peripheral interconnect layer 130 and the array interconnect layer 290. The peripheral interconnect layer 130 and the array interconnect layer 290 may be bonded and coupled to each other through the bonding interface 500.

Referring to the three-dimensional memory 10 shown in FIGS. 1 and 3, the source layer SL is located on a side of the semiconductor structure 200, for example, the source layer SL is located on the lowest plane in the first direction X. One end of the channel structure 410 is connected to the source layer SL. The source layer SL applies a voltage to the channel structure 410 to create a voltage difference between the two ends of the channel structure 410 to drive the channel structure 410 to generate a current. However, as users pursue high-capacity and small-sized three-dimensional memory 10, for 3D NAND, the storage capacity of three-dimensional memory 10 increases by increasing the length of channel structure 410 in the first direction X. As the length of the channel structure 410 in the first direction X increases, the resistance of the channel structure 410 increases, the voltage difference of the channel structure 410 decreases, and the current intensity in the channel structure 410 decreases, which makes it difficult to satisfy the device performance such as the storage speed and the response speed of the three-dimensional memory 10.

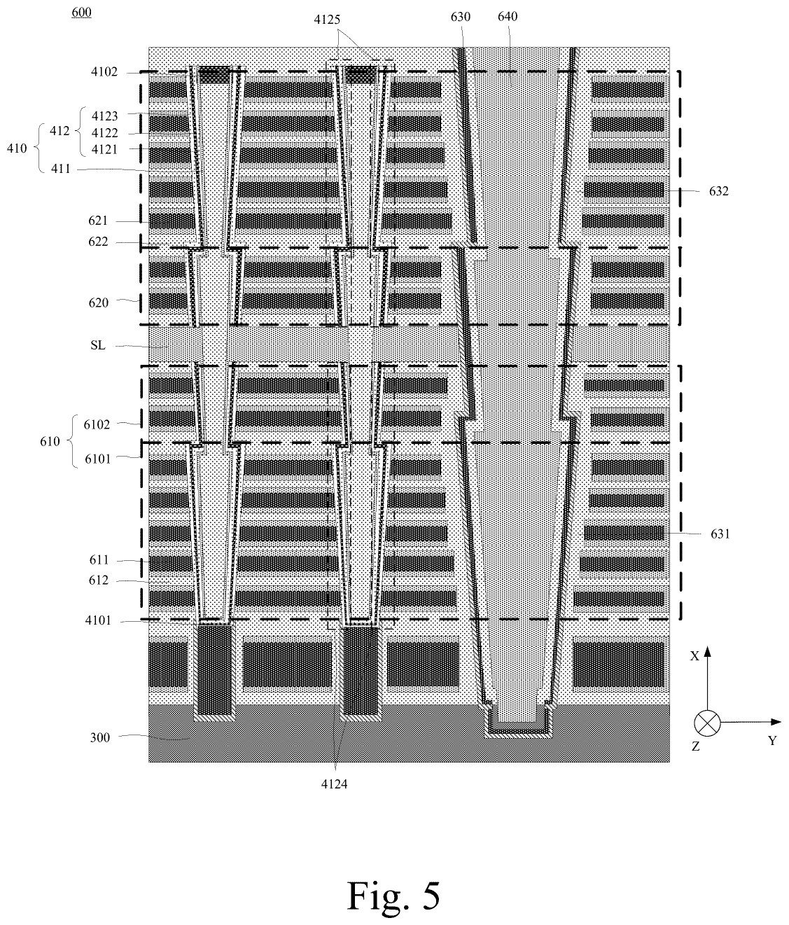

Based on this, some implementations of the present disclosure provide a semiconductor device. FIG. 5 is a schematic structural diagram of a semiconductor device according to some implementations. Referring to FIG. 5, the semiconductor device 600 provided in the present disclosure includes a first stack structure 610, a source layer SL, a second stack structure 620 stacked sequentially along the first direction X, and a channel structure 410, where the channel structure 410 extends through the first stack structure 610, the source layer SL, and the second stack structure 620 along the first direction X, and is connected to the source layer SL.

In this implementation, the first stack structure 610 may be disposed on the semiconductor layer 300. In an example, the first stack structure 610 may be in direct contact with the semiconductor layer 300. The composition materials of semiconductor layer 300 may include, for example, monocrystalline silicon, monocrystalline germanium, group III-V compound semiconductor materials, group II-VI compounds, and other suitable semiconductor materials.

In an example, the first stack structure 610 may include multiple first gate layers 611 and multiple first dielectric layers 612 stacked alternately along the first direction X. For example, the first gate layer 611 and the first dielectric layer 612 disposed alternately along the first direction X are stacked to form multiple first gate layers 611 and multiple first dielectric layers 612 spaced apart from each other. It may also be understood that a first gate layer 611 and a first dielectric layer 612 together form a first gate structure pair, and the first stack structure 610 includes multiple first gate structure pairs stacked along the first direction X.

In an example, the number of layers of the first gate layer 611 and the first dielectric layer 612 may be 4, 16, 32, 64, 128, 256, etc. The thickness of the first gate layer 611 (e.g., the size along the first direction X) may be approximately equal to or different from the thickness of the first dielectric layer 612. For example, the thickness of the first dielectric layer 612 is greater than the thickness of the first gate layer 611.

In an example, the first gate layer 611 may include a conductive material, including but not limited to a combination of one or more of tungsten (W), cobalt (Co), copper (Cu), aluminum (Al), polysilicon, doped silicon, silicide, or other suitable conductive materials. In some examples, the first gate layer 611 includes a metal layer, such as a tungsten layer. In some examples, the first gate layer 611 includes a doped polysilicon layer. The polysilicon may be doped with suitable dopants to a desired doping concentration, so that the polysilicon may become a conductive material used as the first gate layer 611.

In an example, the first dielectric layer 612 may include an insulating material, which may include a combination of one or more of silicon oxide, silicon nitride, silicon oxynitride, and a high dielectric constant insulating material, or other suitable insulating materials, where the dielectric constant of silicon oxynitride is higher than that of silicon oxide. For example, at around 20° C., the dielectric constant of silicon oxynitride is between 4 and 7, such as 3.8, 4, 4.8, 5.3, 5.9, 6, 6.36, 6.88, 7, 7.2, etc. In some examples, the first dielectric layer 612 includes a silicon oxide layer. In some examples, the first dielectric layer 612 includes a silicon oxynitride layer.

In an example, the thickness of the first gate layer 611 (e.g., the size along the first direction X) may be between 10 nm and 50 nm, such as 10 nm, 15 nm, 18.3 nm, 20 nm, 25 nm, 27.7 nm, 30 nm, 35 nm, 40 nm, 45 nm, 50 nm, etc. Similarly, the thickness of the first dielectric layer 612 (e.g., the size along the first direction X) may be between 10 nm and 50 nm, such as 10 nm, 15 nm, 18.3 nm, 20 nm, 25 nm, 27.7 nm, 30 nm, 35 nm, 4 0nm, 45 nm, 50 nm, etc., where the first gate layer 611 may be a gate line G (see FIG. 3) surrounding the memory cell strings, and may extend laterally (e.g. along the third direction Z) as a word line WL (see FIG. 1).

In this implementation, the second stack structure 620 may include multiple second gate layers 621 and multiple second dielectric layers 622 stacked alternately along the first direction X. For example, the second gate layers 621 and the second dielectric layers 622 disposed alternately along the first direction X are stacked to form multiple second gate layers 621 and multiple second dielectric layers 622 spaced apart from each other. It may also be understood that a second gate layer 621 and a second dielectric layer 622 together form a second gate structure pair, and the second stack structure 620 includes multiple second gate structure pairs stacked along the first direction X.

It may be understood that the composition material, thickness, and number of the second gate layers 621 may refer to the example of the composition material, thickness, and number of the first gate layers 611 mentioned above. The composition material, thickness, and number of the second dielectric layers 622 may refer to the example of the composition material, thickness, and number of the first dielectric layers 612 mentioned above. However, the composition material, thickness, and number of the second gate layers 621 and the first gate layers 611 may be the same or different, and the composition material, thickness, and number of the second dielectric layers 622 and the first dielectric layers 612 may be the same or different.

It should be noted that the number of stacked layers of the first stack structure 610 and the second stack structure 620 may be the same or different. The first stack structure 610 may be composed of multiple stack structures, and the second stack structure 620 may also be composed of multiple stack structures, which is not limited by the present disclosure.

In this implementation, the channel structure 410 has a first end 4101 and a second end 4102 disposed along the first direction X. By disposing the source layer SL between the first stack structure 610 and the second stack structure 620, the channel structure 410 extends through the first stack structure 610, the source layer SL, and the second stack structure 620 along the first direction X; and therefore, the connection between the source layer SL and the channel structure 410 may be between the first end 4101 and the second end 4102. In this way, the source layer SL applies a voltage to the channel structure 410, so that a voltage difference may be generated between the connection between the source layer SL and the channel structure 410 and both the first end 4101 and the second end 4102 to drive the channel structure 410 to generate a current.

Compared to the three-dimensional memory in which the source layer SL is connected to the first end 4101 or the second end 4102, the semiconductor device 600 in this implementation shortens the length of the channel structure 410 to be driven by the source layer SL in the first direction X. The problem of increased resistance and reduced voltage difference in the channel structure 410 caused by the increased length of the channel structure 410 can be improved, which is beneficial to improving the current intensity in the channel structure 410, thereby improving the device performance such as storage speed and response speed of the semiconductor device 600.

In addition, disposing the source layer SL between the first stack structure 610 and the second stack structure 620 may also be understood as, for example, with reference to the stack structure and the source layer SL shown in FIG. 1, disposing the source layer SL in the middle of one of the dielectric layers in the stack structure, and dividing the stack structure into the first stack structure 610 and the second stack structure 620 by the source layer SL. Moreover, the source layer SL is connected to the channel structure 410, and the source layer SL may drive the channel structure 410 upward and downward simultaneously to shorten the length of the channel structure 410 to be driven by the source layer SL, so as to increase the current intensity in the channel structure 410, thereby improving the device performance such as storage speed and response speed of the semiconductor device 600.

In some implementations, as shown in FIG. 5, the channel structure 410 includes a channel layer 411 and a functional layer 412, where the channel layer 411 may be made of semiconductor materials, including but not limited to amorphous silicon, polysilicon, or monocrystalline silicon. Carriers (electrons or holes) in the channel layer 411 may be controlled to move or stop by a voltage provided by the first gate layer 611 or the second gate layer 621.

The functional layer 412 is disposed around a portion of the channel layer 411. The functional layer 412 may include a tunneling layer 4121, a storage layer 4122, and a barrier layer 4123 disposed sequentially along a direction away from the channel layer 411. The carriers in the channel layer 411 may tunnel into the storage layer 4122 by the tunneling layer 4121. The storage layer 4122 is configured to store carriers, and the barrier layer 4123 is configured to prevent the carriers from overflowing.

The material of the tunneling layer 4121 may include, but is not limited to, a combination of one or more of silicon oxide and silicon oxynitride. In some examples, the tunneling layer 4121 may be a single-layer dielectric, such as a silicon oxide layer. In other examples, the tunneling layer 4121 may be a composite dielectric layer, such as a layer-stacked structure of a first silicon oxide layer, a first silicon oxynitride layer, a second silicon oxynitride layer, and a second silicon oxide layer.

The material of the barrier layer 4123 may include a combination of one or more of silicon oxide, silicon nitride, and a high dielectric constant material. In some examples, the barrier layer 4123 may be a single-layer dielectric, such as a silicon oxide layer. In other examples, the barrier layer 4123 may be a composite dielectric layer, such as a layer-stacked structure of a silicon nitride layer and an aluminum oxide layer.

The storage layer 4122 is configured to store carriers. The material of storage layer 4122 may include silicon nitride or other suitable materials for storing carriers, and is not limited here.

In this implementation, the channel layer 411 extends through the first stack structure 610, the source layer SL, and the second stack structure 620 along the first direction X, and is connected to the source layer SL. The functional layer 412 includes a first portion 4124 extending through the first stack structure 610 and contacted with the source layer SL, and a second portion 4125 extending through the second stack structure 620 and contacted with the source layer SL. Here, it may be understood that the functional layer 412 is divided into a first portion 4124 and a second portion 4125 by the source layer SL.

By the above arrangements, the length of the channel structure 410 in the first direction X may be increased and the storage capacity of the channel structure 410 may be increased by increasing the number of stacked layers of the first stack structure 610 or the second stack structure 620; and the source layer SL is enabled to be connected to the channel layer 411, so that the source layer SL may apply voltage to the channel layer 411. While increasing the storage capacity of the channel structure 410, the problem of weak current intensity in the channel structure 410 caused by increasing the length of the channel structure 410 is improved.

Regarding the first stack structure 610, the source layer SL, and the second stack structure 620 stacked sequentially along the first direction X, it may be understood that the source layer SL is between the first stack structure 610 and the second stack structure 620, and may also be understood that a stack structure is divided into the first stack structure 610 and the second stack structure 620 by the source layer SL. The following will explain the location of the source layer SL in conjunction with FIGS. 5, 6, and 7.

In some implementations, referring to FIG. 5, the source layer SL may be disposed in a stack structure, dividing the stack structure into a first stack structure 610 and a second stack structure 620. For example, as shown in FIG. 5, the first stack structure 610 may include a first sub-stack structure 6101 and a second sub-stack structure 6102 stacked along the first direction X, where the second sub-stack structure 6102 is between the first sub-stack structure 6101 and the source layer SL. The second stack structure 620 may include a third sub-stack structure 6201 and a fourth sub-stack structure 6202 stacked along the first direction X. The third sub-stack structure 6201 is closer to the second sub-stack structure 6102 than the fourth sub-stack structure 6202. The source layer SL is between the second sub-stack structure 6102 and the third sub-stack structure 6201.

Still referring to FIG. 5, if the first sub-stack structure 6101 and the fourth sub-stack structure 6202 are removed, the second sub-stack structure 6102 and the third sub-stack structure 6201 may be regarded as one stack structure, and the source layer SL is disposed in the middle of one of the dielectric layers in the stack structure, thereby dividing the stack structure into the second sub-stack structure 6102 and the third sub-stack structure 6201. By the above arrangements, the source layer SL may drive the channel structure 410 upward and downward simultaneously, shorten the length of the channel structure 410 to be driven by the source layer SL, to improve the current intensity in the channel structure 410, thereby improving the device performance such as storage speed and response speed of the semiconductor device 600.

Furthermore, one or more stack structures may be further formed on the side of the second sub-stack structure 6102 away from the source layer SL, such as the first sub-stack structure 6101. One or more stack structures may be further formed on the side of the third sub-stack structure 6201 away from the source layer SL, such as the fourth sub-stack structure 6202. The above arrangements allow the length of the channel structure 410 in the first direction X to be further increased, thereby improving the storage capacity of the semiconductor device 600. At the same time, the source layer SL may drive the channel structure 410 upward and downward simultaneously, shorten the length of the channel structure 410 to be driven by the source layer SL, and the problem of weak current intensity in the channel structure 410 caused by increasing the length of the channel structure 410 is improved while increasing the storage capacity of the channel structure 410, thereby improving the device performance such as storage speed and response speed of the semiconductor device 600.

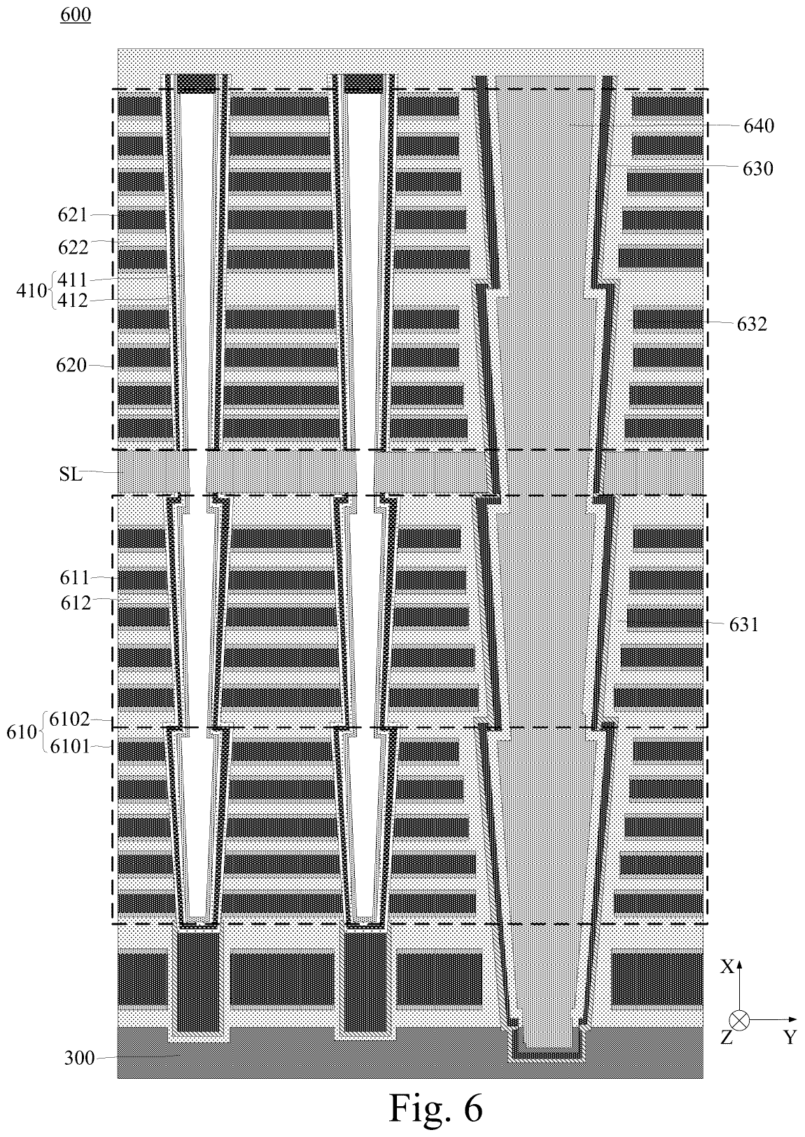

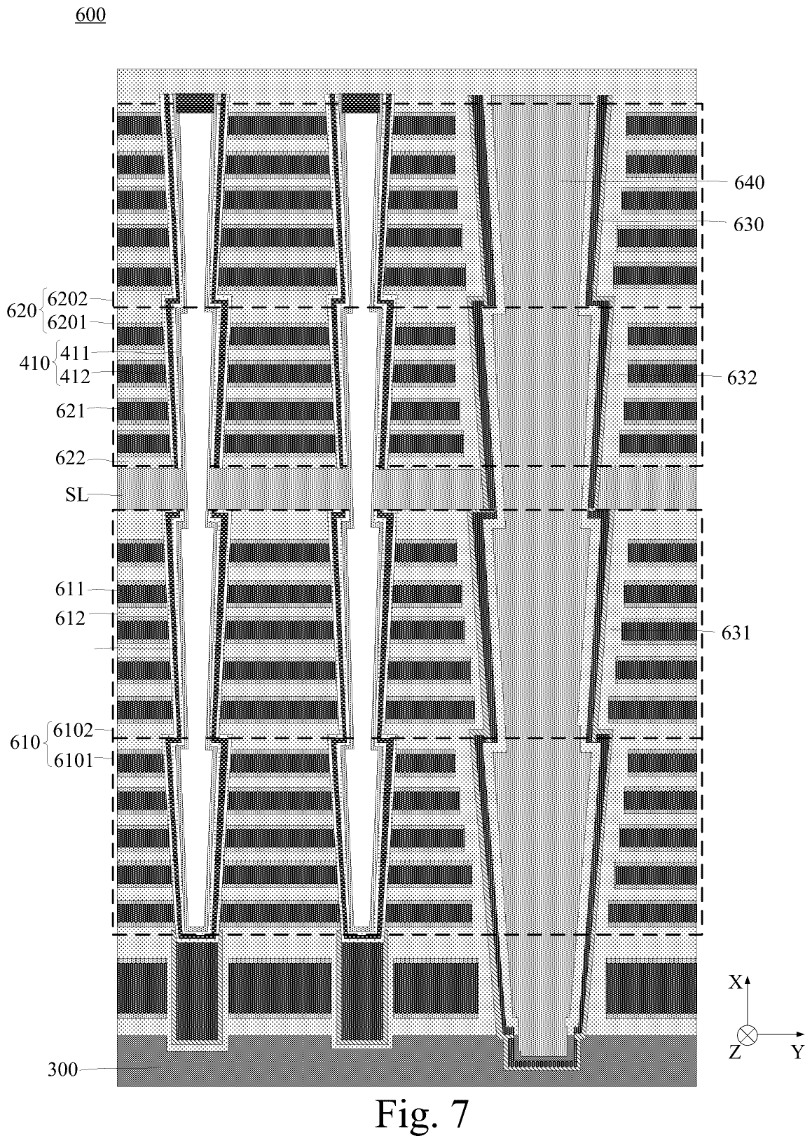

In some other implementations, referring to FIGS. 6 and 7, the source layer SL is between the first stack structure 610 and the second stack structure 620. The first stack structure 610 may include a first sub-stack structure 6101 and a second sub-stack structure 6102 stacked along the first direction X, where the second sub-stack structure 6102 is between the first sub-stack structure 6101 and the source layer SL. For example, one or more stack structures may be further formed on the side of the first sub-stack structure 6101 away from the second sub-stack structure 6102 to increase the length of the channel structure 410 in the first direction X, thereby increasing the storage capacity of the semiconductor device 600. At the same time, the source layer SL may drive the channel structure 410 upward and downward simultaneously, shorten the length of the channel structure 410 to be driven by the source layer SL, and the problem of weak current intensity in the channel structure 410 caused by increasing the length of the channel structure 410 is improved while increasing the storage capacity of the channel structure 410, thereby improving the device performance such as storage speed and response speed of the semiconductor device 600.

In addition, in this implementation, as shown in FIG. 7, the first stack structure 610 and the second stack structure 620 may include the same number of sub-stack structures. For example, the second stack structure 620 may include a third sub-stack structure 6201 and a fourth sub-stack structure 6202 stacked along the first direction X, where the third sub-stack structure 6201 is between the fourth sub-stack structure 6202 and the source layer SL. By the above arrangements, the length of the channel structure 410 in the first direction X is increased, thereby improving the storage capacity of the semiconductor device 600. However, the first stack structure 610 and the second stack structure 620 may also include different numbers of sub-stack structures, and the present disclosure does not limit this.

In some implementations, as shown in FIGS. 5, 6, and 7, the semiconductor device 600 further includes a first connection structure 630. The first connection structure 630 is located on a side of the channel structure 410 along the third direction Z. The first connection structure 630 extends through the first stack structure 610, the source layer SL, and the second stack structure 620 along the first direction X. The first connection structure 630 is connected to the source layer SL. The first connection structure 630 is configured to connect the source layer SL with the peripheral circuit structure for controlling the source layer SL.

In an example, the first connection structure 630 may include a metal layer such as a tungsten layer and a metal barrier layer such as a titanium nitride layer, where the metal barrier layer is disposed around a portion of the metal layer. As a metal barrier layer, titanium nitride is beneficial in preventing material diffusion of the metal layer, and has good adhesion, which is beneficial to improving the structural stability of semiconductor device 600.

In some implementations, as shown in FIGS. 5, 6, and 7, the semiconductor device 600 further includes a gate isolation structure 640. The gate isolation structure 640 extends through the first stack structure 610, the source layer SL, and the second stack structure 620 along the first direction X, and is located on a side of the channel structure 410 along the second direction Y. On a plane parallel to the second direction Y and the third direction Z, the first connection structure 630 is disposed around the gate isolation structure 640. By disposing the first connection structure 630 around the gate isolation structure 640, it is beneficial to save space, thereby reducing the size of the semiconductor device 600 in the second direction Y and the third direction Z, and promoting the miniaturization of the semiconductor device 600.

Since the first connection structure 630 has a conductive function and needs to extend through the first stack structure 610 and the second stack structure 620, if the first connection structure 630 is connected to the first gate layer 611 or the second gate layer 621, the semiconductor device 600 may not work properly.

Based on this, in some implementations, as shown in FIGS. 5, 6, and 7, the semiconductor device 600 further includes a first isolation layer 631 between the first connection structure 630 and the first gate layer 611, and a second isolation layer 632 between the first connection structure 630 and the second gate layer 621. On a plane parallel to the second direction Y and the third direction Z, the first isolation layer 631 may be disposed around the first connection structure 630, which is beneficial to preventing the first connection structure 630 from being connected to the first gate layer 611, so as to enable the semiconductor device 600 to operate normally and improve the storage stability of the semiconductor device 600. On a plane parallel to the second direction Y and the third direction Z, the second isolation layer 632 may also be disposed around the first connection structure 630, which is beneficial to preventing the first connection structure 630 from being connected to the second gate layer 621, so as to enable the semiconductor device 600 to operate normally and improve the storage stability of the semiconductor device 600.

At present, users are pursuing high-capacity and small-sized three-dimensional memory devices. Referring to FIG. 1, in order to increase the capacity of three-dimensional memory 10, the number of stacked layers of gate line G is increasing. However, one gate line G is connected to one gate line contact G-CNT. As the number of layers of gate line G increases, the number of gate line contacts G-CNTs coupled to gate line G also increases, resulting in an increase in the space occupied by gate line contacts G-CNTs, thereby increasing the size of the three-dimensional memory in the third direction Z, which is not conductive to improving the storage density of the three-dimensional memory 10 and is not conductive to the development of the three-dimensional memory 10 towards a smaller volume.

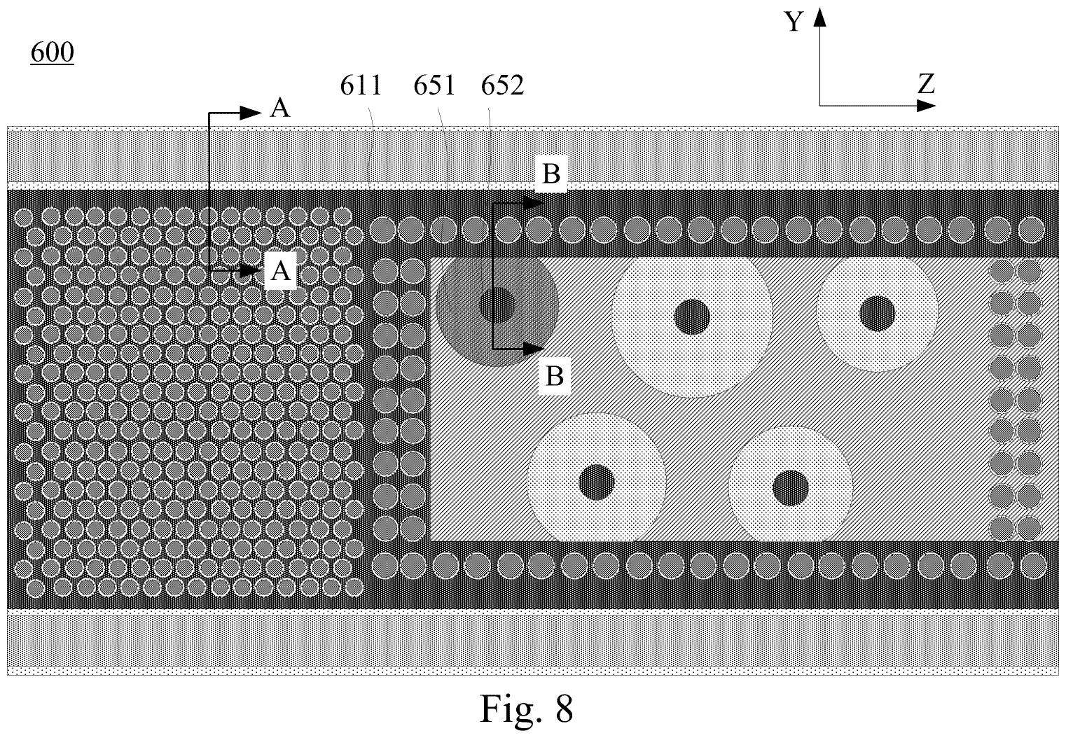

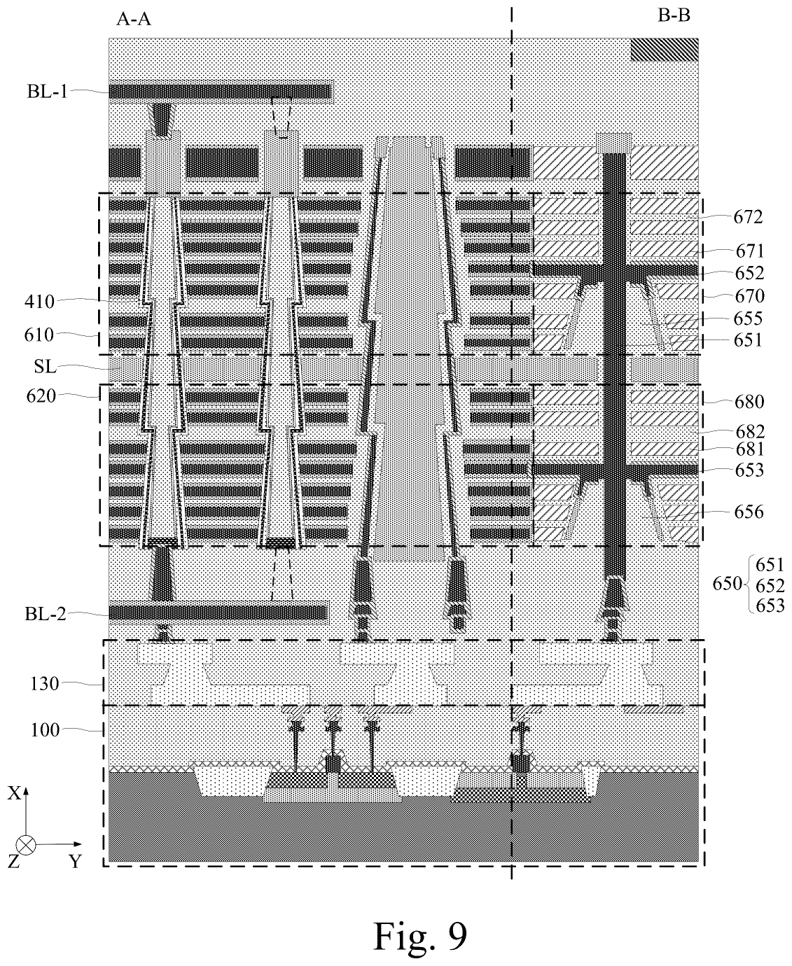

Based on this, in some implementations, as shown in FIGS. 8 and 9, the semiconductor device 600 further includes a second connection structure 650. The second connection structure 650 is located on a side of the first stack structure 610 and the second stack structure 620, connected to at least one first gate layer 611, and connected to at least one second gate layer 621.

It should be noted that FIG. 9 is a splicing diagram. The left side of the dashed line in FIG. 9 is the cross-sectional view taken along A-A in FIG. 8, and the right side of the dashed line in FIG. 9 is the cross-sectional view taken along B-B in FIG. 8.

In this implementation, the semiconductor device 600 may include a first region 101 and a second region 102 abutting each other along the third direction Z. The first stack structure 610 and the second stack structure 620 may both be located in the first region 101, and the second connection structure 650 may be located in the second region 102. The second connection structure 650 connected to at least one first gate layer 611 may be understood that the second connection structure 650 may be connected to one first gate layer 611, or the second connection structure 650 may be connected to multiple first gate layers 611. The second connection structure 650 connected to at least one second gate layer 621 may be understood that the second connection structure 650 may be connected to one second gate layer 621, or the second connection structure 650 may be connected to multiple second gate layers 621. The present disclosure takes the second connection structure 650 connected to one first gate layer 611 and to one second gate layer 621 as an example for explanation.

In an example, the composition material of the second connection structure 650 may include conductive materials. Conductive materials include but are not limited to combinations of one or more of tungsten (W), cobalt (Co), copper (Cu), aluminum (Al), polysilicon, doped silicon, silicides, or other suitable conductive materials.

In this implementation, one second connection structure 650 may be connected to one first gate layer 611 in the first stack structure 610, and to one second gate layer 621 in the second stack structure 620; and the second connection structure 650 may be connected to the peripheral interconnect layer 130 to achieve the transmission of electrical signals between the first gate layer 611 and the second gate layer 621 and the peripheral interconnect layer 130. In an example, the second connection structure 650 may be connected to the peripheral interconnect layer 130 through contacts. One first gate layer 611 and one second gate layer 621 in this implementation may share one second connection structure 650. Compared to the first gate layers 611 connected one-to-one with the gate line contacts G-CNT, and the second gate layers 621 connected one-to-one with the gate line contacts G-CNT, the number of second connection structures 650 is smaller than the number of gate line contacts G-CNT. Therefore, the space occupied by the second connection structures 650 is smaller than that occupied by the gate line contacts G-CNT, which is beneficial to improving the storage density of the semiconductor device 600 and promoting the miniaturization of the semiconductor device 600.

In addition, this solution has strong extensibility. For example, when the semiconductor device 600 includes more stack structures, the semiconductor device 600 may include multiple stack structures such as 4 stack structures, 6 stack structures, or 8 stack structures. At this time, the second connection structure 650 may be connected to one gate layer in each stack structure. By the above arrangements, even if more stack structures are added, the number of second connection structures 650 will not increase, and the occupied space of the second connection structures 650 will not increase, which is beneficial to improving the storage density of the semiconductor device 600 and promoting the development of the semiconductor device 600 towards a larger capacity and a smaller volume.

In some implementations, as shown in FIG. 9, the second connection structure 650 includes a connection pillar 651, at least one first connection layer 652, and at least one second connection layer 653, where the connection pillar 651 extends along the first direction X. The first connection layer 652 is parallel to the second direction Y, and one first connection layer 652 connects the connection pillar 651 and one first gate layer 611. The second connection layer 653 is parallel to the second direction Y, and one second connection layer 653 connects the connection pillar 651 and one second gate layer 621.

In this implementation, in the Y-Z plane, the first connection layer 652 may be disposed around and connected to the connection pillar 651. One first connection layer 652 is configured to connect the connection pillar 651 and one first gate layer 611, as shown in FIG. 8. In this implementation, the first gate layer 611 may also extend along the third direction Z. For example, the first gate layer 611 may extend along the third direction Z to the second region 102, while the first connection layer 652 may extend along the second direction Y and the third direction Z. The first connection layer 652 located in the second region 102 may be connected to a portion of the first gate layer 611 extending to the second region 102. That is, the first connection layer 652 and the first gate layer 611 may be connected in the second direction Y. It should be noted that the first connection layer 652 is configured to connect the first gate layer 611 and the connection pillar 651. The specific connection method between the first connection layer 652 and the first gate layer 611 includes but is not limited to the connection method provided in this implementation, and the present disclosure does not limit this.

Referring to FIGS. 8 and 9, in the Y-Z plane, for example, the cross-section of the connection pillar 651 may be circular, and the cross-section of the first connection layer 652 may be annular. The first connection layer 652 may be disposed around and connected to the connection pillar 651. The outer edge of the first connection layer 652 may be connected to the first gate layer 611.

Similarly, in the Y-Z plane, the second connection layer 653 may be disposed around and connected to the connection pillar 651. One second connection layer 653 connects the connection pillar 651 and one second gate layer 621. The second gate layer 621 may extend along the third direction Z to the second region 102, while the second connection layer 653 is parallel to the second direction Y and the third direction Z. The second connection layer 653 may be connected to a portion of the second gate layer 621 extending to the second region 102. For example, the second connection layer 653 and the second gate layer 621 may be connected in the second direction Y. It should be noted that the second connection layer 653 is configured to connect the second gate layer 621 and the connection pillar 651. The specific connection method between the second connection layer 653 and the second gate layer 621 includes but is not limited to the connection methods provided in this implementation, and the present disclosure does not limit this.

In the Y-Z plane, for example, the cross-section of the connection pillar 651 may be circular, and the cross-section of the second connection layer 653 may be annular. The second connection layer 653 may be disposed around and connected to the connection pillar 651. The outer edge of the second connection layer 653 may be connected to the second gate layer 621.

It should be noted that the second connection structure 650 including at least one first connection layer 652 and at least one second connection layer 653 may be understood that the second connection structure 650 may include one first connection layer 652, or the second connection structure 650 may include multiple first connection layers 652; the second connection structure 650 may include one second connection layer 653, or the second connection structure 650 may include multiple second connection layers 653. When the second connection structure 650 includes multiple first connection layers 652, the multiple first connection layers 652 may be spaced apart along the first direction X; and when the second connection structure 650 includes multiple second connection layers 653, the multiple second connection layers 653 may be spaced apart along the first direction X. The implementation of the present disclosure takes the second connection structure 650 including one first connection layer 652 and one second connection layer 653 as an example for explanation.

In this implementation, the first connection layer 652 is configured to connect the first gate layer 611 and the connection pillar 651, the second connection layer 653 is configured to connect the second gate layer 621 and the connection pillar 651, and the connection pillar 651 is configured to connect with the peripheral interconnect layer 130, to achieve the transmission of electrical signals between the first gate layer 611 and the second gate layer 621 and the peripheral interconnect layer 130. By the above arrangements, one first gate layer 611 and one second gate layer 621 in this implementation may share one second connection structure 650. Compared to the first gate layers 611 connected one-to-one with the gate line contacts G-CNT, and the second gate layers 621 connected one-to-one with the gate line contacts G-CNT, the number of second connection structures 650 is smaller than the number of gate line contacts G-CNT. Therefore, the space occupied by the second connection structures 650 is smaller than that occupied by the gate line contacts G-CNT, which is beneficial to improving the storage density of the semiconductor device 600 and promoting the miniaturization of the semiconductor device 600.

In addition, this solution has strong extensibility. For example, when the semiconductor device 600 includes more stack structures, the semiconductor device 600 may include multiple stack structures such as 4 stack structures, 6 stack structures, or 8 stack structures. At this time, the second connection structure 650 may be connected to one gate layer in each stack structure by increasing the number of connection layers, such as adding a third connection layer, a fourth connection layer, a fifth connection layer, etc. By the above arrangements, even if more stack structures are added, the number of second connection structures 650 will not increase, and the occupied space of the second connection structures 650 will not increase, which is beneficial to improving the storage density of the semiconductor device 600 and promoting the development of the semiconductor device 600 towards a larger capacity and a smaller volume.

In this implementation, the first gate layer 611 farthest from the second stack structure 620 in the multiple first gate layers 611 may be set as the bottom select gate of the first stack structure 610, and the first gate layer 611 closest to the second stack structure 620 in the multiple first gate layers 611 may be set as the top select gate of the first stack structure 610. By the above arrangements, the semiconductor device 600 may further select storage nodes to read from or write to the first stack structure 610 through the top and bottom select gates of the first stack structure 610.

Similarly, the second gate layer 621 farthest from the first stack structure 610 in the multiple second gate layers 621 may be set as the top select gate of the second stack structure 620, and the second gate layer 621 closest to the first stack structure 610 in the multiple second gate layers 621 may be set as the bottom select gate of the second stack structure 620. By the above arrangements, the semiconductor device 600 may further select storage nodes to read from or write to the second stack structure 620 through the top and bottom selection gates of the second stack structure 620.

In turn, if more stack structures continue to be formed, top and bottom select gates may be disposed in multiple gate layers of the stack structure to select storage nodes in a certain stack structure.

In some implementations, as shown in FIG. 9, the connection pillar 651, the first connection layer 652, and the second connection layer 653 are in an integral structure. It may be understood that the connection pillar 651, the first connection layer 652, and the second connection layer 653 are made in one process operation, which is beneficial to enhancing the stability of the electrical connection between the connection pillar 651 and the first connection layer 652, as well as enhancing the stability of the electrical connection between the connection pillar 651 and the second connection layer 653.

In some implementations, as shown in FIG. 9, the semiconductor device 600 further includes a third stack structure 670 and a fourth stack structure 680, where the third stack structure 670 abuts the first stack structure 610 along the third direction Z, and the third stack structure 670 includes third dielectric layers 671 and fourth dielectric layers 672 stacked alternately along the first direction X. That is, the third dielectric layers 671 and the fourth dielectric layers 672 disposed alternately along the first direction X are stacked to form multiple third dielectric layers 671 spaced apart from each other and multiple fourth dielectric layers 672 spaced apart from each other.

It may be understood that the third stack structure 670 abuts the first stack structure 610 along the third direction Z. In an example, the third stack structure 670 may be located in the second region 102 of the semiconductor device 600. When the first stack structure 610 includes multiple sub-stack structures, the third stack structure 670 may also include multiple sub-stack structures correspondingly.

The fourth stack structure 680 and the third stack structure 670 are stacked along the first direction X. The fourth stack structure 680 includes fifth dielectric layers 681 and sixth dielectric layers 682 stacked alternately along the first direction X. That is, the fifth dielectric layers 681 and the sixth dielectric layers 682 disposed alternately along the first direction X are stacked to form multiple fifth dielectric layers 681 spaced apart from each other and multiple sixth dielectric layers 682 spaced apart from each other.

It may be understood that the fourth stack structure 680 may abut the second stack structure 620 along the third direction Z. In an example, the fourth stack structure 680 may be located in the second region 102 of the semiconductor device 600. When the second stack structure 620 includes multiple sub-stack structures, the fourth stack structure 680 may also include multiple sub-stack structures correspondingly.

The connection pillar 651 extends through the third stack structure 670 and the fourth stack structure 680 along the first direction X. At least one third dielectric layer 671 is connected to at least one first connection layer 652, and at least one fifth dielectric layer 681 is connected to at least one second connection layer 653. Here, the first connection layer 652 connected to the third dielectric layer 671 may be connected to the first gate layer 611, and the second connection layer 653 connected to the fifth dielectric layer 681 may be connected to the second gate layer 621.

In an example, the third dielectric layer 671 may be connected to the first gate layer 611, and the fourth dielectric layer 672 may be connected to the first dielectric layer 612. In addition, the composition material of the fourth dielectric layer 672 may be the same as that of the first dielectric layer 612. Furthermore, the fourth dielectric layer 672 may be same-layer-disposed as the first dielectric layer 612. Same-layer-disposing refers to multiple patterns on the same pattern layer, and the pattern layer refers to a film layer formed by a one-time patterning process. Patterning process refers to the process capable of forming at least one pattern with a certain shape. For example, a thin film is formed on a substrate 710 by any of various film-forming processes such as deposition, coating, sputtering, etc., and then patterned to form a film layer containing at least one pattern, which is called a pattern layer. The operations of patterning include photoresist coating, exposure, development, etching, and photoresist stripping, etc. In this implementation, the positional relationship between multiple patterns belonging to the same pattern layer is referred to as the same-layer-disposing.

In an example, the fifth dielectric layer 681 may be connected to the second gate layer 621, and the sixth dielectric layer 682 may be connected to the second dielectric layer 622. In addition, the composition material of the sixth dielectric layer 682 may be the same as that of the second dielectric layer 622. Furthermore, the sixth dielectric layer 682 may be same-layer-disposed as the second dielectric layer 622. For example, the composition materials of the first dielectric layer 612, the second dielectric layer 622, the fourth dielectric layer 672, and the sixth dielectric layer 682 are all oxides, and the composition materials of the third dielectric layer 671 and the fifth dielectric layer 681 are all nitrides.

Referring to FIG. 1, when G-CNTs are formed, since each G-CNT needs to extend to different gate layers, the process of forming G-CNTs is relatively difficult.

In this implementation, the connection pillar 651 of the second connection structure 650 extends through the third stack structure 670 and the fourth stack structure 680. Compared to extending G-CNT to different gate layers, the difficulty of the process of manufacturing the second connection structure 650 is lower, which is therefore beneficial to reducing the difficulty of the process of manufacturing the semiconductor device 600 and improving the manufacturing efficiency of the semiconductor device 600.

In some implementations, as shown in FIG. 9, the source layer SL is between the third stack structure 670 and the fourth stack structure 680, and the connection pillar 651 extends through the source layer SL. The semiconductor device 600 also includes a third isolation layer 654. The third isolation layer 654 is disposed around the connection pillar 651 and is between the connection pillar 651 and the source layer SL. The third isolation layer 654 may cover the circumferential surface of the connection pillar 651, isolating the connection pillar 651 from the source layer SL and preventing electrical connection between the connection pillar 651 and the source layer SL, which is beneficial to protecting the normal operation of the semiconductor device 600 and improving the storage stability of the semiconductor device 600.

In some implementations, as shown in FIG. 9, the second connection structure 650 further includes a fourth isolation layer 655 and a fifth isolation layer 656, where the fourth isolation layer 655 is located on the side of the first connection layer 652 close to the second connection layer 653, and the fourth isolation layer 655 is disposed around the connection pillar 651. For example, the fourth isolation layer 655 may cover the circumferential surface of the connection pillar 651 to isolate the connection pillar 651 and prevent leakage current generated between the connection pillar 651 and other conductive structures, which is beneficial to improving the storage stability of the semiconductor device 600.

Moreover, the fifth isolation layer 656 is located on the side of the second connection layer 653 away from the first connection layer 652, and is disposed around the connection pillar 651. For example, the fifth isolation layer 656 may cover the circumferential surface of the connection pillar 651 to isolate the connection pillar 651 and prevent leakage current generated between the connection pillar 651 and other conductive structures, which is beneficial to improving the storage stability of the semiconductor device 600.

In some implementations, as shown in FIG. 9, the size of the end of the fourth isolation layer 655 away from the first connection layer 652 in the second direction is greater than that of the end of the fourth isolation layer 655 close to the first connection layer 652 in the second direction. In the second direction Y, the fourth isolation layer 655 has a certain thickness, and the thickness of the end of the fourth isolation layer 655 close to the connection pillar 651 may be greater than that of the end of the fourth isolation layer 655 close to the first connection layer 652. In this way, it is beneficial to further improve the isolation effect of the end of the connection pillar 651 close to the connection pillar 651.

Still referring to FIG. 9, in the second direction Y, the fifth isolation layer 656 has a certain thickness, and the thickness of the end of the fifth isolation layer 656 away from the connection pillar 651 may be greater than that of the end of the fifth isolation layer 656 close to the connection pillar 651. In this way, it is beneficial to further improve the isolation effect of the fifth isolation layer 656 on the end of the connection pillar 651 away from the connection pillar 651.

In an example, the composition materials of the fourth isolation layer 655 and the fifth isolation layer 656 may include insulating materials, such as silicon oxide, silicon nitride, and a combination of one or more of high dielectric constant insulating materials, or other insulating materials. The composition materials of the fourth isolation layer 655 and the fifth isolation layer 656 may be the same or different.

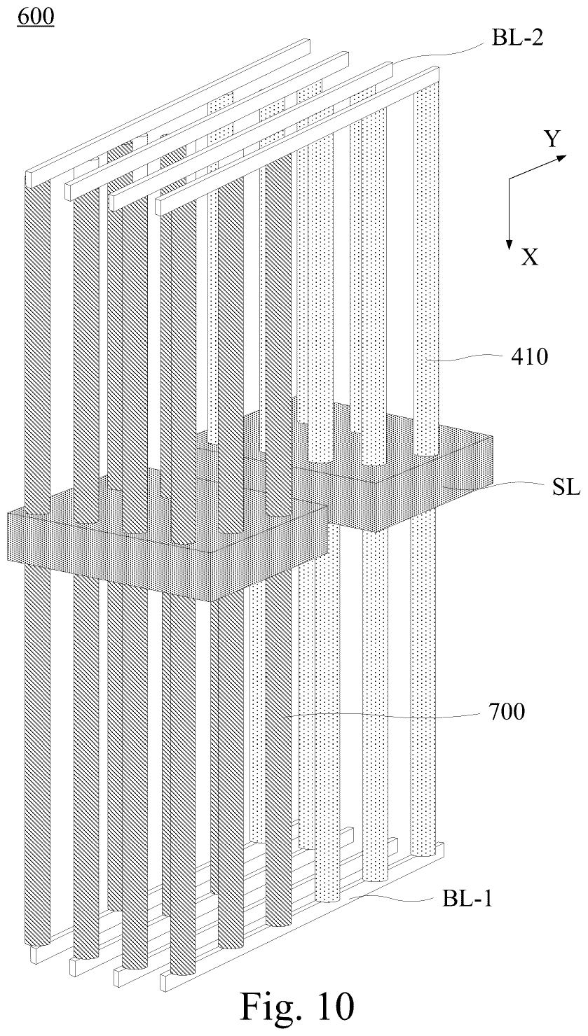

In some implementations, as shown in FIG. 10, the semiconductor device 600 further includes a first bit line BL-1 and a second bit line BL-2, where the first bit line BL-1 extends in a direction intersecting with the first direction X and is located on the side of the first stack structure 610 away from the second stack structure 620. The first bit line BL-1 is connected to the channel structure 410. The second bit line BL-2 extends in a direction intersecting with the first direction X and is located on the side of the second stack structure 620 away from the first stack structure 610. The second bit line BL-2 is connected to the channel structure 410. The extending direction of the first bit line BL-1 may be parallel to that of the second bit line BL-2.

In an example, the first bit line BL-1 may extend in the Y-Z plane, and the extending direction of the first bit line BL-1 may be parallel to the second direction Y. The number of first bit lines BL-1 may be multiple, and multiple first bit lines BL-I are spaced along the third direction Z.

In an example, the second bit line BL-2 may extend in the Y-Z plane, and the extending direction of the second bit line BL-2 may be parallel to the second direction Y. The number of second bit lines BL-2 may be multiple, and multiple second bit lines BL-2 are spaced along the third direction Z. The number of channel structures 410 is also multiple, and one channel structure 410 is connected to one first bit line BL-1 and to one second bit line BL-2.

In this implementation, the first bit line BL-1 is electrically connected to the second bit line BL-2, thereby driving the channel structure 410 through the first bit line BL-1 and the second bit line BL-2. In an example, the first bit line BL-1 and the second bit line BL-2 may be connected to the peripheral interconnect layer 130, respectively, achieving electrical connection through the peripheral interconnect layer 130.

In some implementations, as shown in FIG. 10, the semiconductor device 600 further includes a third connection structure 700. The third connection structure 700 extends through the first stack structure 610, the source layer SL, and the second stack structure 620. The third connection structure 700 is connected to the first bit line BL-1, and to the second bit line BL-2. In an example, two ends of the third connection structure 700 along the first direction X are connected to the first bit line BL-1 and the second bit line BL-2, respectively.

In an example, the number of third connection structures 700 may be multiple, and multiple third connection structures 700 may be arranged in multiple rows along the second direction Y and in multiple columns along the third direction Z. Two ends of a third connection structure 700 along the first direction X are connected to one first bit line BL-1 and one second bit line BL-2.

Connecting the first bit line BL-1 and the second bit line BL-2 by the third connection structure 700 is beneficial for the first bit line BL-1 and the second bit line BL-2 to share the same circuit. In this way, the first bit line BL-1 and the second bit line BL-2 may be controlled simultaneously by one circuit, which is beneficial for simplifying the circuit layout, reducing the use of metal wiring, and controlling costs.

In some other implementations, the first bit line BL-1 and the second bit line BL-2 may be connected to two circuits, respectively, so that the first bit line BL-1 and the second bit line BL-2 may be controlled respectively by the two circuits. The above arrangement requires more metal wirings, but the first bit line BL-1 and the second bit line BL-2 may be controlled by the two circuits, respectively, so as to select the channel structure 410 in the first stack structure 610 or the channel structure 410 in the second stack structure 620, without additionally providing a select gate.

Therefore, the first bit line BL-1 and the second bit line BL-2 may be connected through the third connection structure 700, sharing the same circuit. Alternatively, the first bit line BL-1 and the second bit line BL-2 may be controlled by two circuits, which may be selected according to specific circuit designs and actual needs.

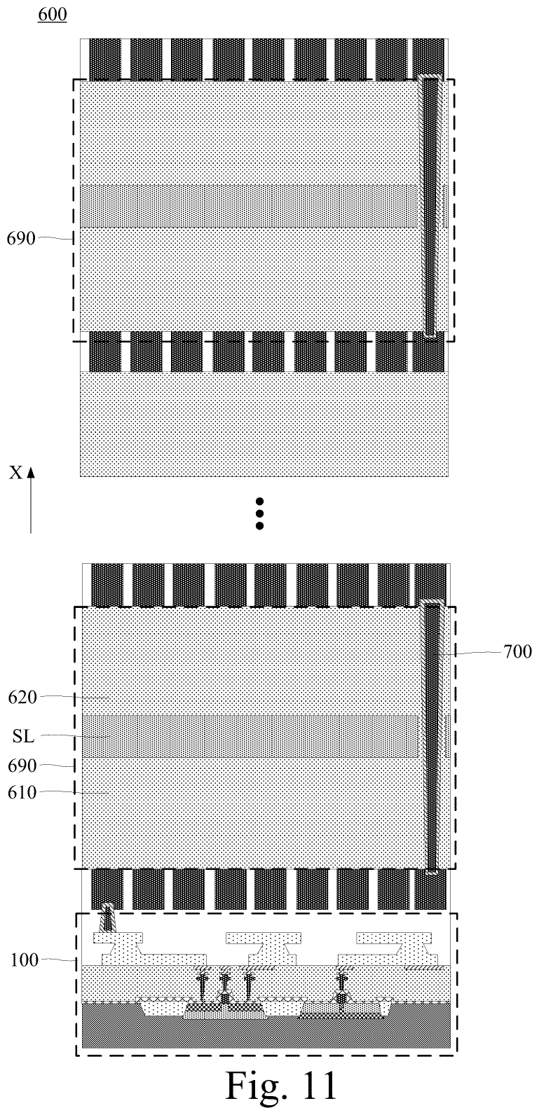

In some implementations, as shown in FIG. 11, the first stack structure 610, the source layer SL, and the second stack structure 620 collectively constitute a repeating structure 690. The number of repeating structures 690 may be multiple, and multiple repeating structures 690 are stacked along the first direction X. The source layers SL in multiple repeating structures 690 may be interconnected. The repeating structure 690 located at the topmost or bottommost end among the multiple repeating structures 690 is electrically connected to the peripheral device 100. That is, multiple repeating structures 690 may share a peripheral device 100, thereby performing operations such as storing or reading on the channel structure 410 in multiple repeating structures 690.

It should be noted that the stacked layers of the multiple repeating structures 690 may be the same or different, which may be understood as the stacked layers of the multiple first stack structures 610 may be the same or different, and the stacked layers of the multiple second stack structures 620 may be the same or different, and the present disclosure does not limit this.

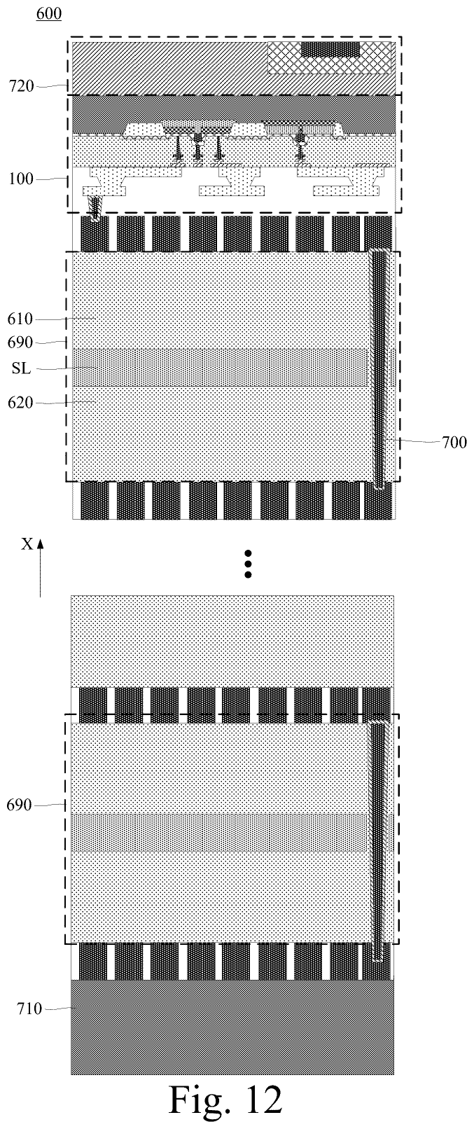

In some implementations, as shown in FIG. 12, multiple repeating structures 690 may be disposed on the substrate 710. The peripheral device 100 may be placed on the side of multiple repeating structures 690 away from the substrate 710, and connected to the repeating structures 690.

In an example, the semiconductor device 600 may also include a pad 720. The pad 720 may be located on the side of the peripheral device 100 away from the repeating structure 690, and electrically connected to the peripheral device 100 for supplying power to the semiconductor device 600.

It should be noted that in some other implementations, the pad 720 may also be located on the side of the multiple repeating structures 690 away from the peripheral device 100, and connected to the multiple repeating structures 690 for supplying power to the semiconductor device 600.

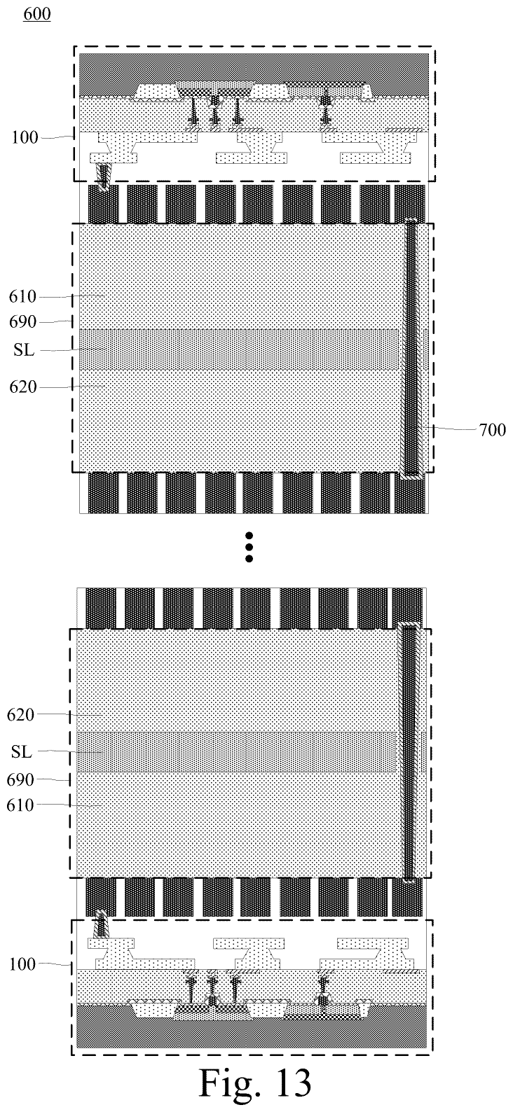

In some implementations, as shown in FIG. 13, the number of peripheral devices 100 may be multiple. Multiple repeating structures 690 may be located between two adjacent peripheral devices 100 along the first direction X. Moreover, the two peripheral devices 100 are respectively electrically connected to the repeating structure 690 located at both ends, to achieve electrical signal transmission between the peripheral devices 100 and the repeating structure 690.

This implementation may achieve control of the channel structure 410 in multiple repeating structures 690 by the peripheral device 100, thereby realizing the writing, reading, and erasing of data by the channel structure 410.

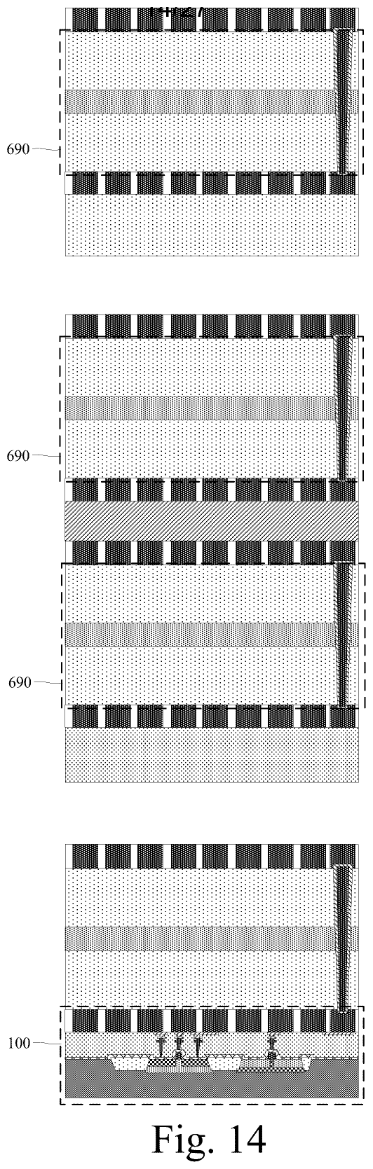

In some other implementations, as shown in FIG. 14, when it is not possible to form more repeating structures 690 on one wafer, the repeating structures 690 on two wafers may be bonded together, and the source layers SL of multiple repeating structures 690 in the same set may be interconnected. Two sets of repeating structures 690 share one peripheral device 100. The peripheral device 100 may be located on the side of a set of repeating structures 690 away from another set of repeating structures 690.

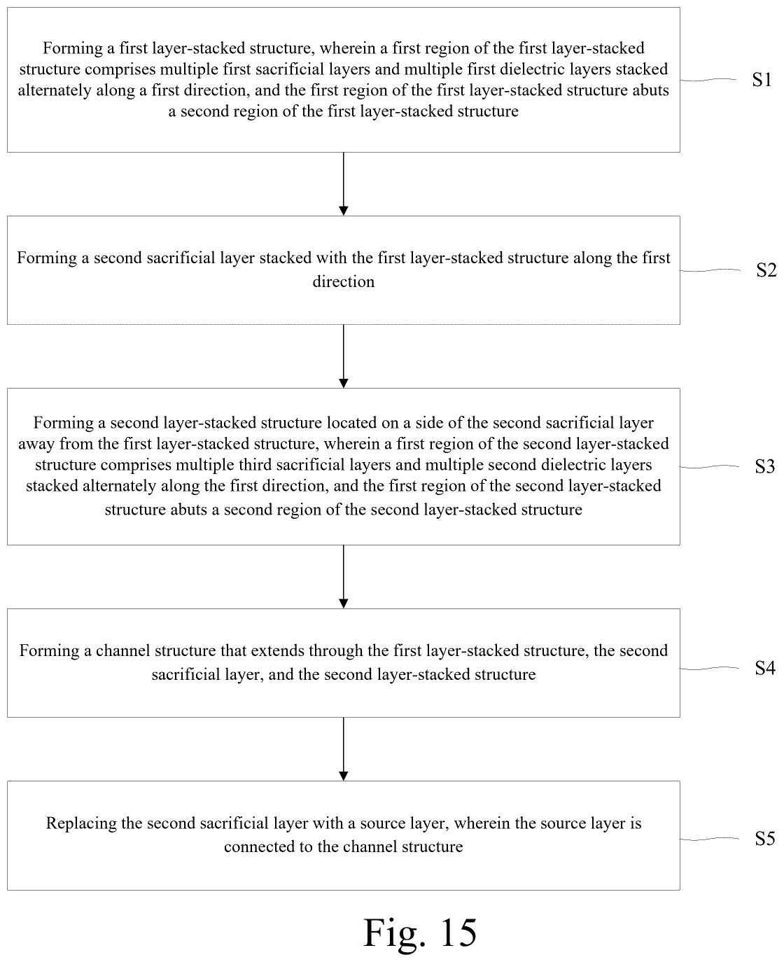

Some implementations of the present disclosure further provide a method of manufacturing a semiconductor device. The following will explain a method of manufacturing a semiconductor device 600 in conjunction with FIGS. 15 to 24.

FIG. 15 is a flowchart of a method of manufacturing a semiconductor device 600 according to some implementations. As shown in FIG. 15, the method of manufacturing the semiconductor device provided in some implementations of the present disclosure includes operations S1-S6.

At operation S1, the method may include forming a first layer-stacked structure, where a first region of the first layer-stacked structure includes multiple first sacrificial layers and multiple first dielectric layers stacked alternately along a first direction, and the first region of the first layer-stacked structure abuts a second region of the first layer-stacked structure.

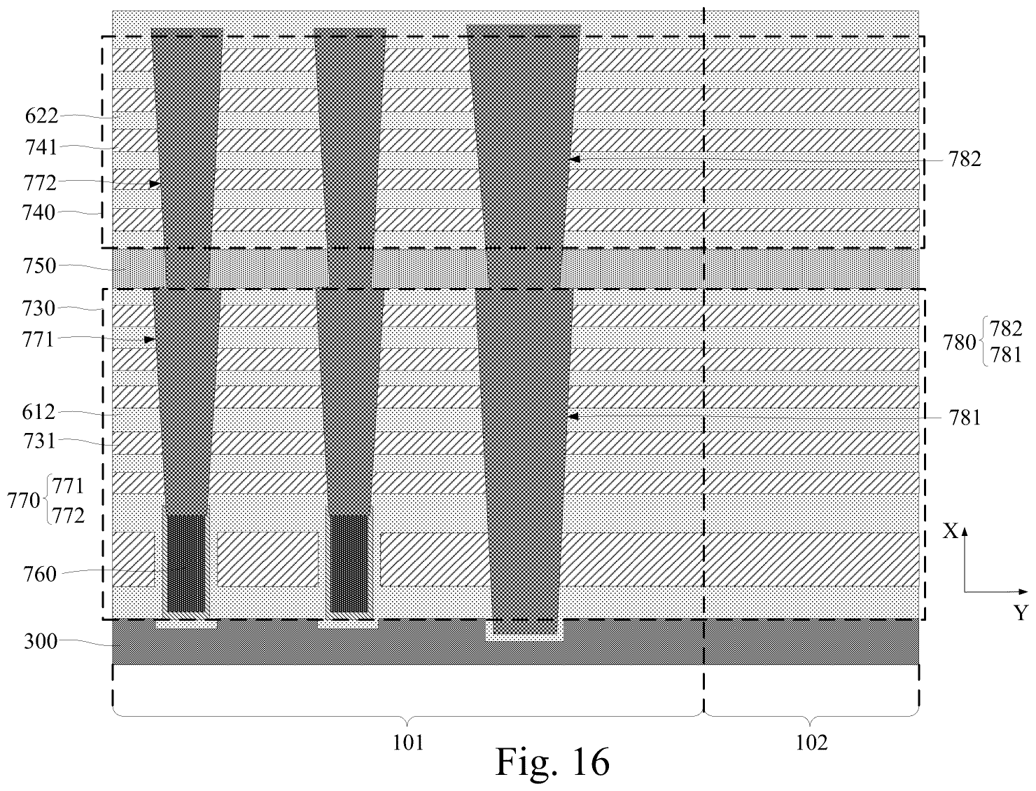

At operation S1, as shown in FIG. 16, for example, the first dielectric layer 612 and the first sacrificial layer 731 may be formed alternately on the semiconductor layer 300 by a deposition process. The deposition process includes but is not limited to one or more thin film deposition processes such as Physical Vapor Deposition (PVD), Chemical Vapor Deposition (CVD), and Atomic Layer Deposition (ALD).

Where the semiconductor layer 300 may include at least one of silicon (e.g., monocrystalline silicon, polysilicon), silicon germanium (SiGe), gallium arsenide (GaAs), germanium (Ge), silicon on insulator (SOI), or any other suitable semiconductor material.

The composition material of the first dielectric layer 612 may include an insulating material, which may include a combination of one or more of silicon oxide, silicon nitride, silicon oxynitride, and high dielectric constant insulating materials, or other suitable insulating materials, where the dielectric constant of silicon oxynitride is higher than that of silicon oxide. For example, at around 20° C., the dielectric constant of silicon oxynitride is between 4 and 7, such as 3.8, 4, 4.8, 5.3, 5.9, 6, 6.36, 6.88, 7, 7.2, etc.

Since the first sacrificial layer 731 needs to be removed in subsequent manufacturing operations, the composition material of the first sacrificial layer 731 needs to be different from that of the first dielectric layer 612 to prevent damage to the first dielectric layer 612 when removing the first sacrificial layer 731. This implementation takes the composition material of the first dielectric layer 612 being silicon oxide and the composition material of the first sacrificial layer 731 being silicon nitride as an example for explanation.

At operation S2, the method may include forming a second sacrificial layer stacked with the first layer-stacked structure along the first direction.

At operation S2, still referring to FIG. 16, for example, the second sacrificial layer 750 may be formed on the first layer-stacked structure 730 by using one or more thin film deposition processes including but not limited to PVD, CVD, ALD. The material of the second sacrificial layer 750 may include polysilicon, for example.

At operation S3, the method may include forming a second layer-stacked structure located on the side of the second sacrificial layer away from the first layer-stacked structure, where a first region of the second layer-stacked structure includes multiple third sacrificial layers and multiple second dielectric layers stacked alternately along the first direction, and the first region of the second layer-stacked structure abuts a second region of the second layer-stacked structure.

At operation S3, still referring to FIG. 16, the second dielectric layer 622 and the third sacrificial layer 741 may be formed alternately on the second sacrificial layer 750 by using one or more thin film deposition processes including but not limited to PVD, CVD, ALD.

The composition material of the second dielectric layer 622 may include an insulating material, which may include a combination of one or more of silicon oxide, silicon nitride, silicon oxynitride, and a high dielectric constant insulating material, or other suitable insulating materials.

Since the third sacrificial layer 741 needs to be removed in subsequent manufacturing operations, the composition material of the third sacrificial layer 741 needs to be different from that of the second dielectric layer 622 to prevent damage to the second dielectric layer 622 when removing the third sacrificial layer 741. This implementation takes the composition material of the second dielectric layer 622 being silicon oxide and the composition material of the third sacrificial layer 741 being silicon nitride as an example for explanation.

In some implementations, referring to FIG. 16, after forming the first layer-stacked structure 730 and before forming the second sacrificial layer 750, the manufacturing method further includes removing a portion of the first layer-stacked structure 730 to form a first channel hole 771, where the first channel hole 771 extends through the first region 101 of the first layer-stacked structure 730.

In this operation, the first channel hole 771 may be formed by any suitable manufacturing process. For example, a patterned photoresist layer may be formed on the first layer-stacked structure 730. The patterned photoresist layer may expose a portion of the first layer-stacked structure 730 configured to form the first channel hole 771. An appropriate etching process may be performed to remove the portion of the first layer-stacked structure 730 configured to form the first channel hole 771. For example, the etching process may include a dry etching process.

After forming the first channel hole 771, the patterned photoresist layer on the first layer-stacked structure 730 may be removed. For example, the surface of the first layer-stacked structure 730 may be planarized by chemical mechanical polishing (CMP) to remove the patterned photoresist layer on the first sub-layer-stacked structure 7301.

After removing the patterned photoresist layer on the first layer-stacked structure 730, a deposition process may be used to fill a sacrificial material, such as carbon, in the first channel hole 771, so as to facilitate formation of the second layer-stacked structure 740 on the first layer-stacked structure 730 in subsequent manufacturing operations.

It should be noted that in order to easily determine the position of the first channel hole 771, a structural stub 760 may be formed on the semiconductor layer 300 before forming the first layer-stacked structure 730. In forming the first channel hole 771 subsequently, the first channel hole 771 may extend through the first layer-stacked structure 730 to the structural stub 760, so as to determine the position of the first channel hole 771.

After forming the second layer-stacked structure 740, the manufacturing method further includes removing a portion of the second layer-stacked structure 740 and a portion of the second sacrificial layer 750 to form a second channel hole 772, where the second channel hole 772 extends through the first region 101 of the second layer-stacked structure 740, and is in communication with the first channel hole 771, and the first channel hole 771 and the second channel hole 772 collectively constitute a channel hole 770.

In this operation, for example, a dry etching process may be used to remove a portion of the second layer-stacked structure 740 and a portion of the second sacrificial layer 750 to form the second channel hole 772. The second channel hole 772 is in communication with the first channel hole 771, and the first channel hole 771 and the second channel hole 772 collectively constitute a channel hole 770.

After forming the second channel hole 772, the sacrificial material in the first channel hole 771 may be removed. I example, when the sacrificial material includes carbon, the process of removing the sacrificial material in the first channel hole 771 may include ashing to remove all of the sacrificial material.

In this implementation, removing the portion of the layer-stacked structure to form the channel hole 770 further includes forming a gate line slit 780, where the gate line slit 780 is in the first region 101 of the first layer-stacked structure 730 and the first region 101 of the second layer-stacked structure 740, and is located on a side of the channel hole 770 along a second direction Y, and extends along the second direction Y.

In an example, when forming the first channel hole 771, a portion of the first layer-stacked structure 730 is removed simultaneously to form the first gate line slit 781. When forming the second channel hole 772, a portion of the second layer-stacked structure 740 is removed simultaneously to form the second gate line slit 782. The first gate line slit 781 and the second gate line slit 782 are in communication with each other and collectively constitute the gate line slit 780.

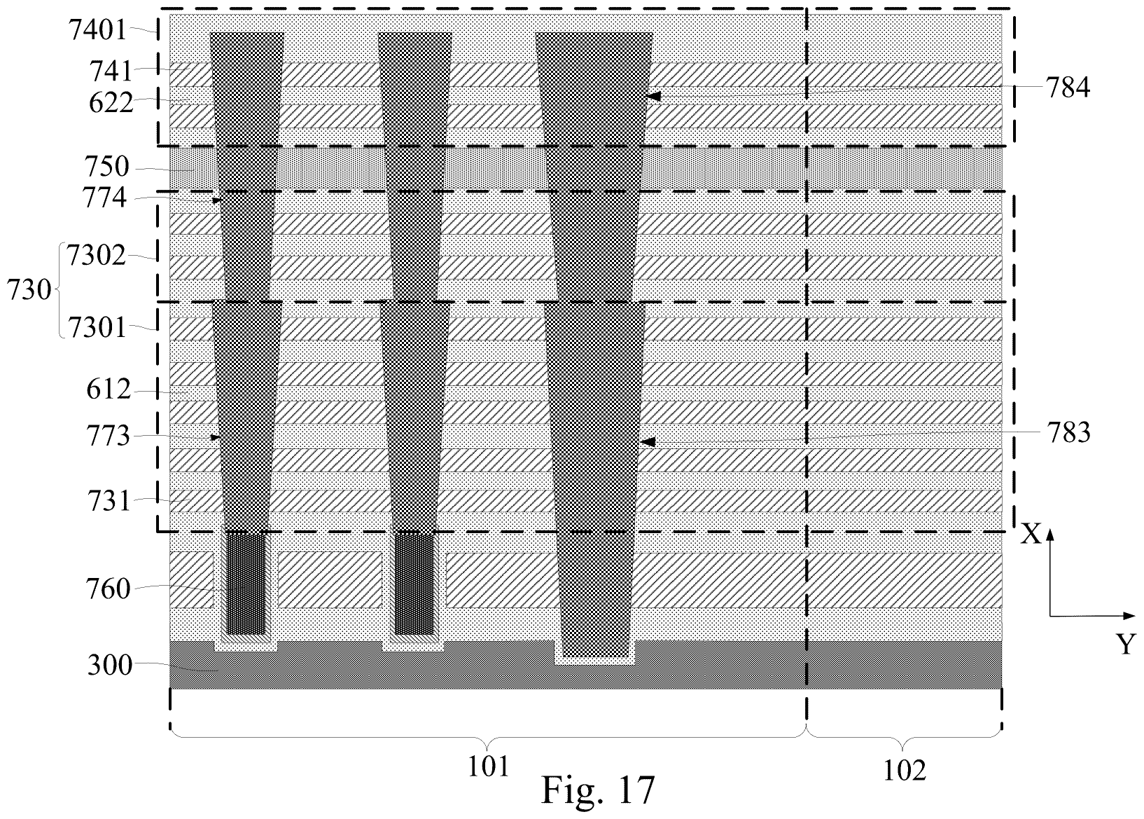

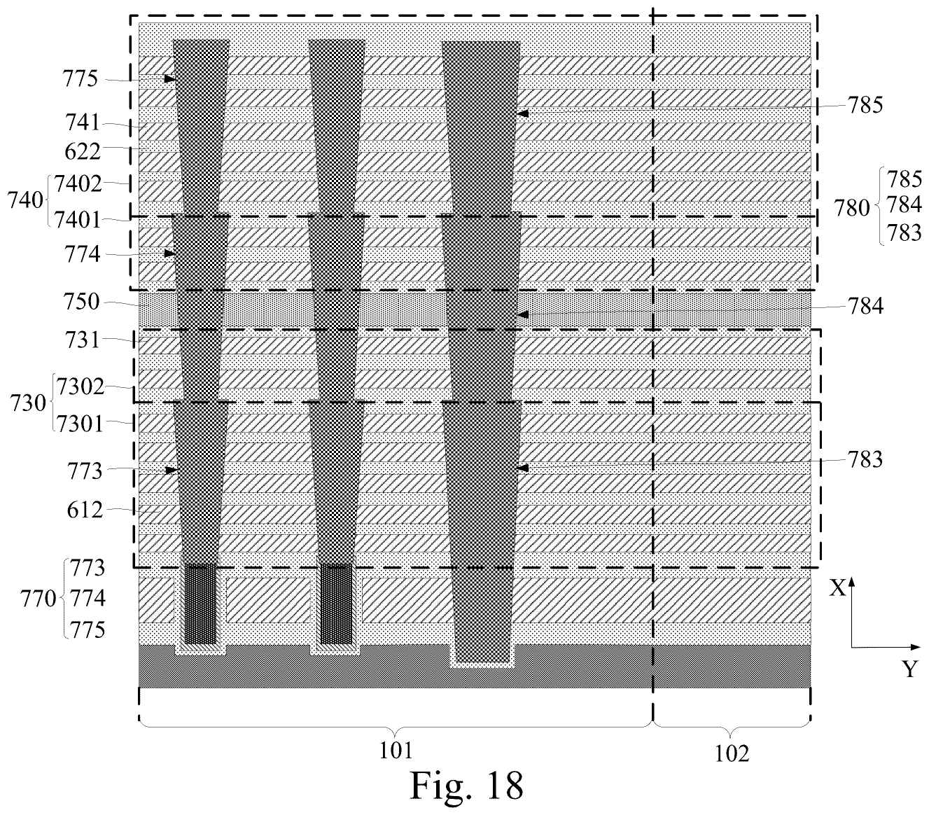

In some other implementations, referring to FIGS. 17 and 18, forming the first layer-stacked structure 730 may include forming a first sub-layer-stacked structure 7301.

In this operation, for example, a deposition process may be used to alternately form the first dielectric layer 612 and the first sacrificial layer 731 on the semiconductor layer 300, to form the first region 101 of the first sub-layer-stacked structure 7301.

After forming the first sub-layer-stacked structure 7301, a portion of the first sub-layer-stacked structure 7301 is removed to form a third channel hole 773, which extends through the first region 101 of the first sub-layer-stacked structure 7301.

In this operation, referring to FIG. 17, for example, a dry etching process may be used to remove a portion of the first sub-layer-stacked structure 7301 to form the third channel hole 773. In an example, in order to easily determine the position of the third channel hole 773, a structural stub 760 may be formed on the semiconductor layer 300 before forming the first sub-layer-stacked structure 7301. In forming the third channel hole 773 subsequently, the third channel hole 773 may extend through the first sub-layer-stacked structure 7301 to the structural stub 760, so as to determine the position of the third channel hole 773.

After forming the third channel hole 773, a deposition process may be used to fill a sacrificial material, such as carbon, in the third channel hole 773, so as to facilitate formation of the second sub-layer-stacked structure 7302 on the first sub-layer-stacked structure 7301 in subsequent manufacturing operations.

Still referring to FIG. 17, after forming the third channel hole 773, the manufacturing method further includes: forming a second sub-layer-stacked structure 7302 stacked with the first sub-layer-stacked structure 7301 along the first direction X.

In this operation, for example, a deposition process may be used to alternately form the first dielectric layer 612 and the first sacrificial layer 731 on the first sub-layer-stacked structure 7301.

Still referring to FIG. 17, after forming the second sub-layer-stacked structure 7302, a second sacrificial layer 750 may be formed on the second sub-layer-stacked structure 7302 by a deposition process. After forming the second sacrificial layer 750, a second layer-stacked structure 740 is formed, where forming the second layer-stacked structure 740 may include: forming a third sub-layer-stacked structure 7401 stacked with the second sacrificial layer 750 along the first direction X.

In this operation, as shown in FIG. 17, a deposition process may be used to alternately form the second dielectric layer 622 and the third sacrificial layer 741 on the side of the second sacrificial layer 750 away from the second sub-layer-stacked structure 7302, to form the third sub-layer-stacked structure 7401.

As shown in FIG. 17, after forming the third sub-layer-stacked structure 7401, the manufacturing method further includes removing a portion of the second sub-layer-stacked structure 7302, a portion of the second sacrificial layer 750, and a portion of the third sub-layer-stacked structure 7401 to form a fourth channel hole 774, which is connected to the third channel hole 773.

In this operation, a dry etching process may be used to remove a portion of the second sub-layer-stacked structure 7302, a portion of the second sacrificial layer 750, and a portion of the third sub-layer-stacked structure 7401 to form the fourth channel hole 774. The fourth channel hole 774 extends through the second sub-layer-stacked structure 7302, the second sacrificial layer 750, and the third sub-layer-stacked structure 7401 to the third channel hole 773. Subsequently, a deposition process may be used to fill a sacrificial materials, such as carbon, in the fourth channel hole 774, so as to facilitate formation of the third sub-layer-stacked structure 7401 on the second sub-layer-stacked structure 7302 in subsequent manufacturing operations. In addition, the sacrificial material filled in the fourth channel hole 774 is the same as that filled in the third channel hole 773, which is beneficial for removing together in one process operation subsequently.

Referring to FIG. 18, after forming the fourth channel hole 774, the manufacturing method further includes forming a fourth sub-layer-stacked structure 7402 stacked with the third sub-layer-stacked structure 7401 along the first direction X.

In this operation, for example, a deposition process may be used to alternately form the second dielectric layer 622 and the third sacrificial layer 741 on the side of the third sub-layer-stacked structure 7401 away from the second sacrificial layer 750, to form the fourth sub-layer-stacked structure 7402.

Still referring to FIG. 18, after forming the fourth sub-layer-stacked structure 7402, the manufacturing method further includes: removing a portion of the fourth sub-layer-stacked structure 7402 to form a fifth channel hole 775, which is connected to the fourth channel hole 774. The third channel hole 773, the fourth channel hole 774, and the fifth channel hole 775 collectively constitute the channel hole 770.

In this operation, a dry etching process may be used to remove a portion of the fourth sub-layer-stacked structure 7402 to form a fifth channel hole 775 that extends through the fourth sub-layer-stacked structure 7402. Subsequently, the sacrificial material in the third and fourth channel holes 773 and 774 is removed. In an example, when the sacrificial material includes carbon, the process of removing the sacrificial material in the third and fourth channel holes 773 and 774 may include ashing to remove all of the sacrificial material. The third channel hole 773, the fourth channel hole 774, and the fifth channel hole 775 are in communication with each other and collectively constitute the channel hole 770.

In this implementation, removing a portion of a stack structure to form the channel hole 770 further includes forming a gate line slit 780, where the gate line slit is located in the first region 101 of the first layer-stacked structure 730 and the first region 101 of the second layer-stacked structure 740, and is located on a side of the channel hole 770 along the second direction Y, and the gate line slit 780 may extend along the third direction Z.

In an example, when forming the third channel hole 773, a portion of the first sub-layer-stacked structure 7301 is removed simultaneously to form a third gate line slit 783. When forming the fourth channel hole 774, a portion of the second sub-layer-stacked structure 7302, a portion of the second sacrificial layer 750, and a portion of the third sub-layer-stacked structure 7401 are removed simultaneously to form a fourth gate line slit 784. When forming the fifth channel hole 775, a portion of the fourth sub-layer-stacked structure 7402 is removed simultaneously to form a fifth gate line slit 785. The third gate line slit 783, the fourth gate line slit 784, and the fifth gate line slit 785 are in communication with each other and collectively constitute the gate line slit 780.

At operation S4, the method may include forming a channel structure that extends through the first layer-stacked structure, the second sacrificial layer, and the second layer-stacked structure.

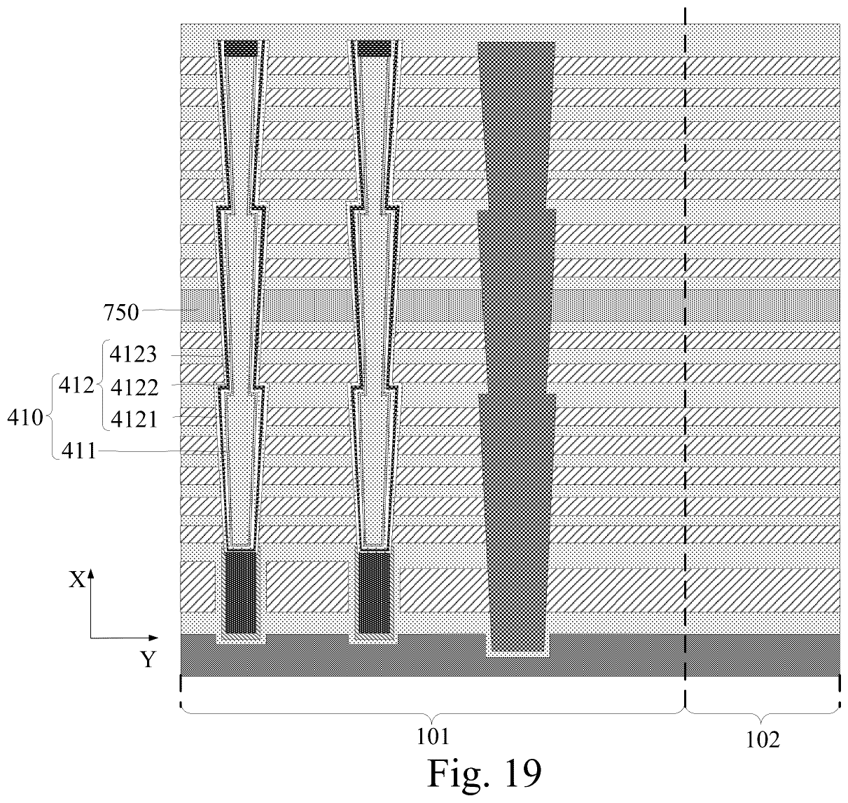

At operation S4, referring to FIG. 19, one or more thin film deposition processes including but not limited to PVD, CVD, ALD may be used to sequentially form a functional layer 412 and a channel layer 411 in the channel hole 770, the functional layer 412 disposed around the channel layer 411, where forming the functional layer 412 in the channel hole 770 includes sequentially forming a barrier layer 4123, a storage layer 4122, and a tunneling layer 4121 in the channel hole 770. For example, the material of the tunneling layer 4121 may include, but is not limited to, a combination of one or more of silicon oxide and silicon oxynitride. The material of the barrier layer 4123 may include a combination of one or more of silicon oxide, silicon nitride, and a high dielectric constant material. The material of the storage layer 4122 may include silicon nitride or other suitable materials for storing carriers. The material of the channel layer 411 may include but is not limited to amorphous silicon, polysilicon, or monocrystalline silicon.

At operation S5, the method may include replace the second sacrificial layer with a source layer, where the source layer is connected to the channel structure.

Referring to FIGS. 19, 20, and 21, this operation includes removing a portion of the second sacrificial layer 750 to form a first filling space 751, which exposes a portion of the functional layer 412. In an example, a wet etching process may be used to, for example, by injecting an etching solution into the gate line slit 780, remove the portion of the second sacrificial layer 750.

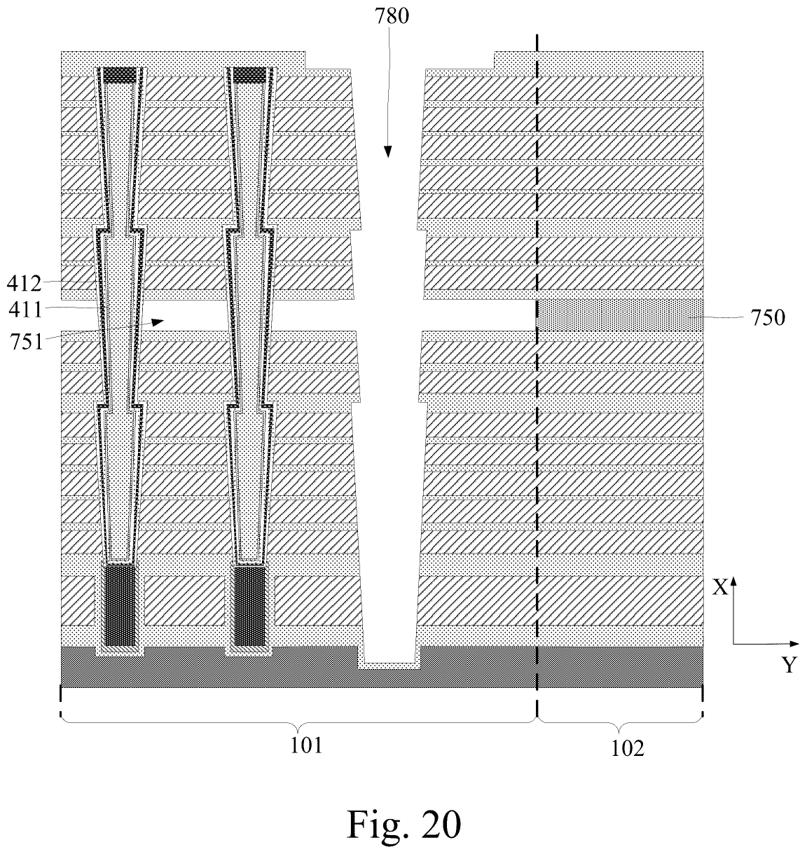

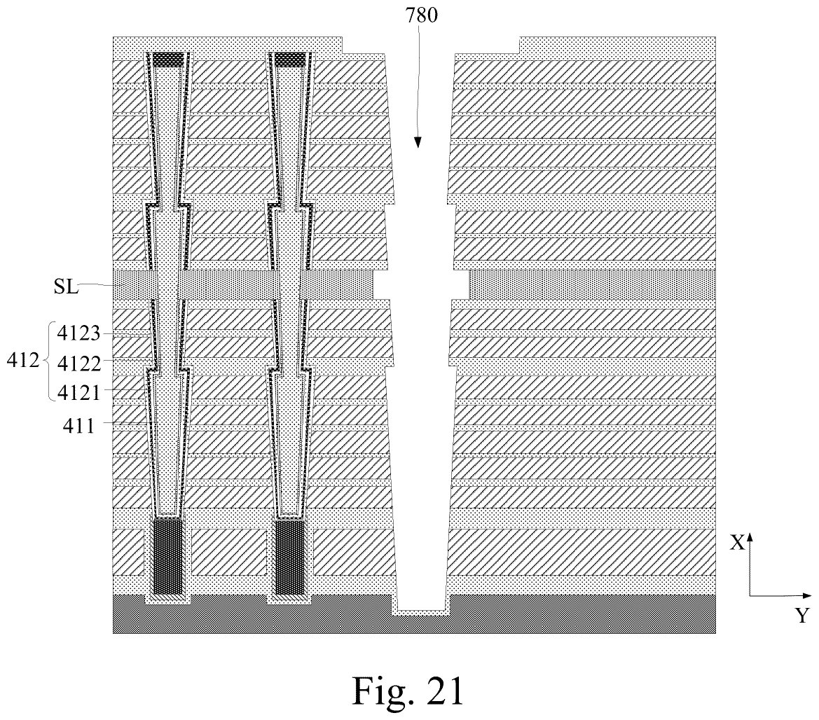

Referring to FIGS. 20 and 21, after forming the first filling space 751, the manufacturing method further includes: removing a portion of the functional layer 412 by the first filling space 751, and dividing the functional layer 412 into a first portion 4124 and a second portion 4125, where the first portion 4124 extends through the first layer-stacked structure 730, and the second portion 4125 extends through the second layer-stacked structure 740.

In this operation, for example, a wet etching process may be used to, by injecting an etching solution into the gate line slit 780 and the first filling space 751, remove the functional layer 412 exposed in the first filling space 751 and expose a portion of the channel layer 411.

After removing a portion of the functional layer 412 through the first filling space 751, one or more thin film deposition processes including but not limited to PVD, CVD, ALD may be used to fill a semiconductor material, such as polysilicon, in the first filling space 751 to form the source layer SL; and the source layer SL is connected to the channel layer 411 exposed in the first filling space 751.

Here, it should be noted that in the operation of forming the second sacrificial layer 750, the second sacrificial layer 750 may be formed by a deposition process depositing a polysilicon material. It may be understood that the composition material of the second sacrificial layer 750 may be the same as that of the source layer SL. Therefore, after forming the source layer SL in the first filling space 751, the source layer SL is connected to the second sacrificial layer 750 that has not been removed. At this time, the second sacrificial layer 750 that has not been removed is also considered as the source layer SL.

At operation S6, the method may include replacing the first sacrificial layer with the first gate layer and replacing the third sacrificial layer with the second gate layer.

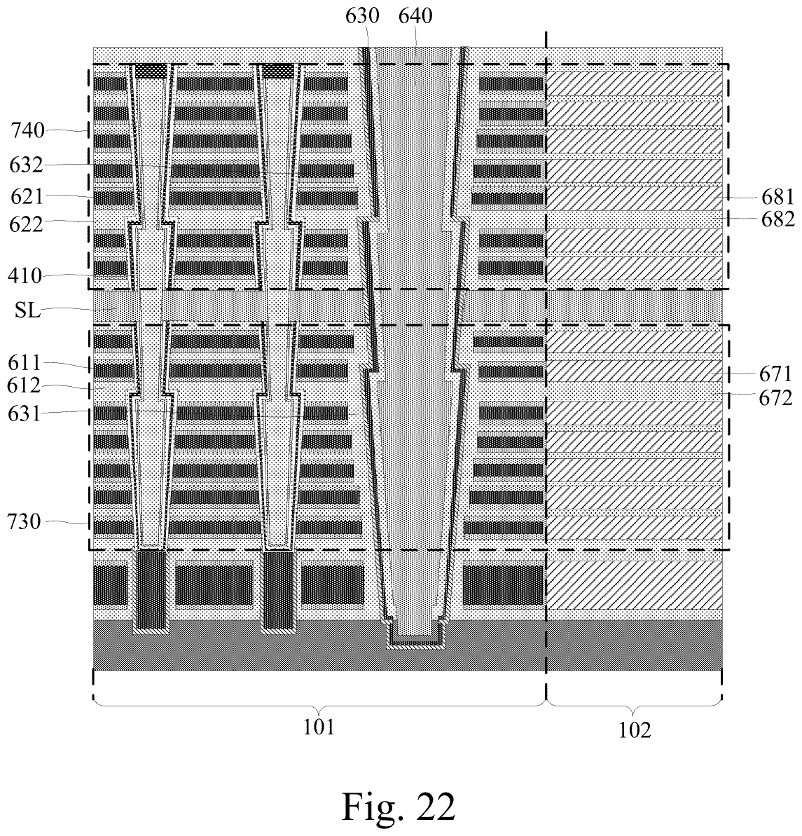

Referring to FIGS. 21 and 22, in this operation, a wet etching process may be used to remove the first sacrificial layer 731 and the third sacrificial layer 741 through the gate line slit 780. Then, one or more thin film deposition processes including but not limited to PVD, CVD, ALD may be used to deposit a conductive material at the location of the original first sacrificial layer 731 to form the first gate layer 611, and at the location of the original third sacrificial layer 741 to form the second gate layer 621. In an example, the conductive materials include but are not limited to combinations of one or more of tungsten (W), cobalt (Co), copper (Cu), aluminum (Al), polysilicon, doped silicon, silicides, or other suitable conductive materials. In some examples, the composition material of the first gate layer 611 may include a doped polysilicon layer. The polysilicon may be doped with suitable dopants to a desired doping concentration, so that the polysilicon may become a conductive material used as the first gate layer 611.

After replacing the first sacrificial layer 731 with the first gate layer 611 and replacing the third sacrificial layer 741 with the second gate layer 621, the first region 101 of the first layer-stacked structure 730 constitutes the first stack structure 610 (referring to FIG. 9), and the first region 101 of the second layer-stacked structure 740 constitutes the second stack structure 620 (referring to FIG. 9).

The semiconductor device 600 manufactured by the above manufacturing method shortens the length of the channel structure 410 to be driven by the source layer SL in the first direction X. The problem of increased resistance and reduced voltage difference in the channel structure 410 caused by the increased length of the channel structure 410 may be improved, which is beneficial to improving the current intensity in the channel structure 410, thereby improving the device performance such as storage speed and response speed of the semiconductor device 600.

In some implementations, referring to FIGS. 21 and 22, after replacing the first sacrificial layer 731 with the first gate layer 611, the manufacturing method further includes: forming an isolation layer, a first connection structure 630, and a gate isolation structure 640 sequentially in the gate line slit 780, where the first connection structure 630 is disposed around the gate isolation structure 640 and is connected to the source layer SL, the isolation layer is disposed around the first connection structure 630, the isolation layer between the first connection structure 630 and the first gate layer 611 constitutes a first isolation layer 631, and the isolation layer between the first connection structure 630 and the second gate layer 621 constitutes a second isolation layer 632.

It should be noted that after filling a semiconductor material in the first filling space 751 to form the source layer SL, the semiconductor material will be attached to the sidewalls of the gate line slit 780. In order to easily removing the first sacrificial layer 741 through the gate line slit 780 subsequently, an etching process, such as a wet etching process, may be used to remove the semiconductor material attached to the sidewalls of the gate line slit 780. In the above operations, a portion of the source layer SL may be removed. After replacing the first sacrificial layer 741 with the first gate layer 611 and replacing the third sacrificial layer 721 with the second gate layer 621, a conductive material will be attached to the sidewalls of the gate line slit 780. In order to isolate the first gate layer 611 and the second gate layer 621, an etching process, such as a wet etching process, may be used to remove the conductive material attached to the sidewalls of the gate line slit 780 through the gate line slit 780, and to remove a portion of the first gate layer 611 and a portion of the second gate layer 621 along the second direction. Here, the size of the removed first gate layer 611 in the second direction Y is larger than that of the removed source layer SL in the second direction Y, and the size of the removed second gate layer 621 in the second direction Y is larger than that of the removed source layer SL in the second direction Y.

In this operation, for example, one or more thin film deposition processes including but not limited to PVD, CVD, ALD may be used to deposit an insulating material in the gate line slit 780 to form the isolation layer 633. Since the size of the removed first gate layer 611 in the second direction Y is larger than that of the removed source layer SL in the second direction Y, after depositing the insulating material in the gate line slit 780, the insulating material on the side of the first gate layer 611 is thicker than that on the source layer SL in the second direction Y. For the same reason, after depositing the insulating material in the gate line slit 780, the insulating material on the side of the second gate layer 621 is thicker than that on the side of the source layer SL in the second direction Y. By the above operations, it is beneficial to remove the insulating material located on the side of the source layer, expose the source layer SL through the gate line slit 780, and retain a portion of the insulating material located on the side of the first gate layer 611 and a portion of the insulating material located on the side of the second gate layer 621 to form the isolation layer 633.

After depositing the insulating material in the gate line slit 780 to form the isolation layer 633, a metal material may be deposited in the gate line slit 780 by a deposition process to form a first connection structure 630. The first connection structure 630 is connected to the first connection structure 630 exposed in the gate line slit 780, and then the insulating material is deposited in the gate line slit 780 by a deposition process to form the gate isolation structure 640.

In some implementations, referring to FIG. 22, when removing a portion of a layer-stacked structure to form the channel hole 770, the manufacturing method further includes forming a connection hole 791 that extends through the second region 102 of the first layer-stacked structure 730 and the second region 102 of the second layer-stacked structure 740, where the second region 102 of the first stack structure 730 includes multiple third dielectric layers 671 and multiple fourth dielectric layers 672 stacked alternately along the first direction, and the second region 102 of the second layer-stacked structure 740 includes multiple fifth dielectric layers 681 and multiple sixth dielectric layers 682 stacked alternately along the first direction.

It should be noted that the second region 102 of the first layer-stacked structure 730 includes third dielectric layers 671 and fourth dielectric layers 672 stacked alternately along the first direction X, where the third dielectric layer 671 and the first sacrificial layer 731 may be film layers formed by a one-time patterning process. The fourth dielectric layer 672 and the first dielectric layer 612 may be film layers formed by a one-time patterning process. Patterning process refers to the process capable of forming at least one pattern with a certain shape. For example, a thin film is formed on a substrate 710 through any of various film-forming processes such as deposition, coating, sputtering, etc., and then patterned to form a film layer containing at least one pattern, which is called a pattern layer. The operations of patterning include photoresist coating, exposure, development, etching, and photoresist stripping, etc. In an example, the composition material of the third dielectric layer 671 is the same as that of the first sacrificial layer 731. The insulation material may be deposited by a deposition process, meanwhile the first sacrificial layer 731 is formed in the first region 101 and the third dielectric layer 671 is formed in the second region 102. The insulation material may be deposited by a deposition process, meanwhile the first dielectric layer 612 is formed in the first region 101 and the fourth dielectric layer 672 is formed in the second region 102. In an example, the insulating material may include a combination of one or more of silicon oxide, silicon nitride, silicon oxynitride, and a high dielectric constant insulating material, or other suitable insulating materials. Since the first sacrificial layer 731 needs to be removed, the material used to form the first sacrificial layer 731 needs to be different from the first dielectric layer 612 and the fourth dielectric layer 672.

The second region 102 of the second layer-stacked structure 740 includes fifth dielectric layers 681 and sixth dielectric layers 682 stacked alternately along the first direction X, where the fifth dielectric layer 681 and the second sacrificial layer 750 may be film layers formed by a one-time patterning process. The sixth dielectric layer 682 and the second dielectric layer 622 may be film layers formed by a one-time patterning process. In an example, the composition material of the fifth dielectric layer 681 is the same as that of the second sacrificial layer 750. Silicon nitride material may be deposited by a deposition process, meanwhile the first sacrificial layer 731 is formed in the first region 101 and the fifth dielectric layer 681 is formed in the second region 102. Silicon oxide material may be deposited by a deposition process, meanwhile the second dielectric layer 622 is formed in the first region 101 and the sixth dielectric layer 682 is formed in the second region 102.

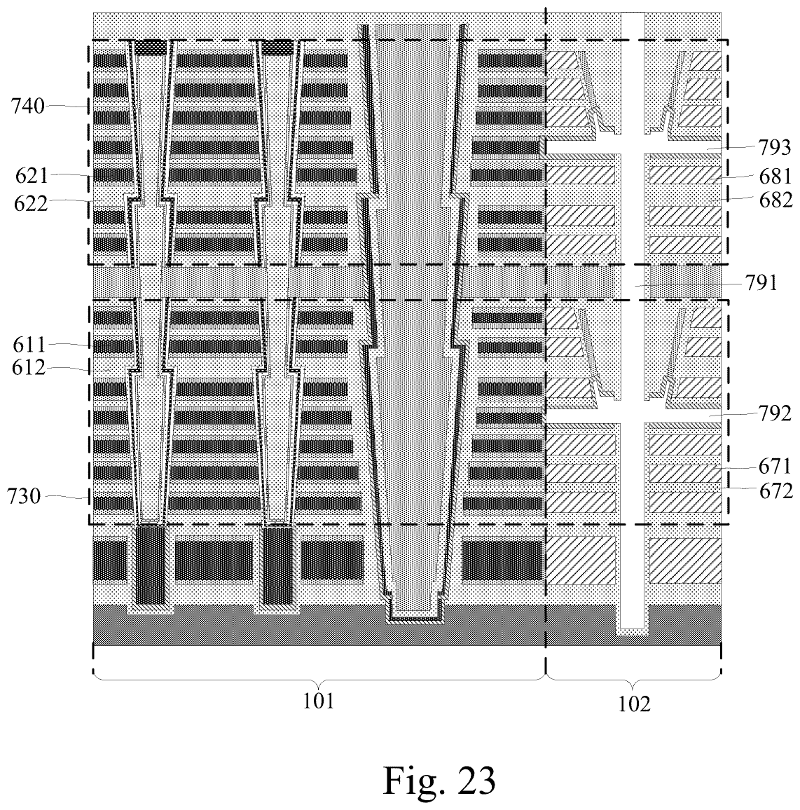

Referring to FIGS. 22 and 23, after sequentially forming the isolation layer, the first connection structure 630, and the gate isolation structure 640 in the gate line slit 780, the manufacturing method further includes removing a portion of the third dielectric layer 671 and the fifth dielectric layer 681 to form a second filling space 792 and a third filling space 793. The second filling space 792 exposes at least one first gate layer 611, and the third filling space 793 exposes at least one second gate layer 621. The second filling space 792 is in communication with the connection hole 791, and the third filling space 793 is in communication with the connection hole 791.

In this operation, for example, a wet etching process may be used to remove a portion of the third dielectric layer 671 and a portion of the fifth dielectric layer 681 by the connection hole 791, to form the second filling space 792 and the third filling space 793.

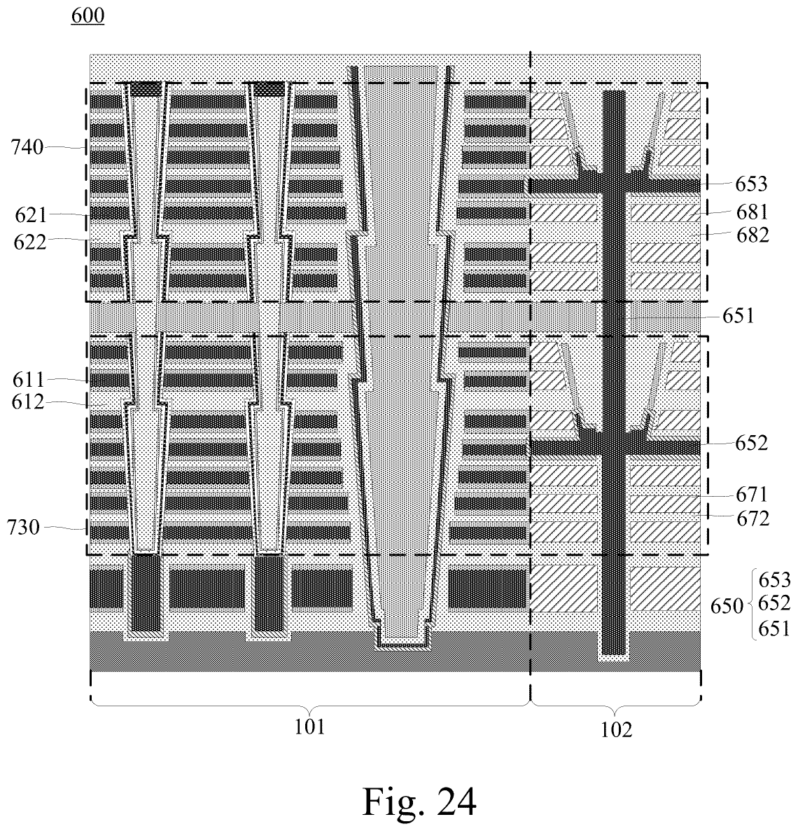

Referring to FIGS. 23 and 24, after forming the second filling space 792 and the third filling space 793, the method further includes: filling a conductive material in the connection hole 791 to form the second connection structure 650.

In this operation, for example, one or more thin film deposition processes including but not limited to PVD, CVD, ALD may be used to fill the conductive material in the connection hole 791 to form the second connection structure 650. In an example, conductive materials may include but are not limited to a combination of one or more of tungsten (W), cobalt (Co), copper (Cu), aluminum (Al), polysilicon, doped silicon, silicides, or other suitable conductive materials.

The semiconductor device 600 formed by the above manufacturing method does not increase the number of second connection structures 650 even if more stack structures are formed. Therefore, the occupied space of the second connection structures 650 of the semiconductor device 600 obtained by the above manufacturing method will not increase as the number of stack structures increases, which is beneficial to improving the storage density of the semiconductor device 600 and promoting the development of the semiconductor device 600 towards a larger capacity and a smaller volume.

In some implementations, referring to FIG. 9, after forming the second connection structure 650, a first bit line BL-1 is formed where the first bit line BL-1 extends in a direction intersecting with the first direction X and is located on the side of the first layer-stacked structure 730 away from the second layer-stacked structure 740, and is connected to the channel structure 410.

In this operation, for example, a contact may be formed on the channel structure 410. The contact is connected to the channel structure 410 and exposed on the side of the first layer-stacked structure 730 away from the second layer-stacked structure 740. A deposition process may be used to deposit a conductive material on the side of the first layer-stacked structure 730 away from the second layer-stacked structure 740 to form the first bit line BL-1. And the first bit line BL-1 may be connected to the contact. The first bit line BL-1 may be connected to the channel structure 410 by the contact.

After forming the first bit line BL-1, the second bit line BL-2 is formed, where the second bit line BL-2 extends in a direction intersecting with the first direction X and is located on the side of the second layer-stacked structure 740 away from the first layer-stacked structure 730, and is connected to the channel structure 410.

In this operation, the method of forming the second bit line BL-2 may refer to the method of forming the first bit line BL-1 mentioned above, which will not be repeated here.

After forming the second bit line BL-2, the first bit line BL-1 is connected to the second bit line BL-2. For example, by connecting the first bit line BL-1 to the peripheral interconnect layer 130 and connecting the second bit line BL-2 to the peripheral interconnect layer 130, the first bit line BL-1 and the second bit line BL-2 may be connected by the peripheral interconnect layer 130.

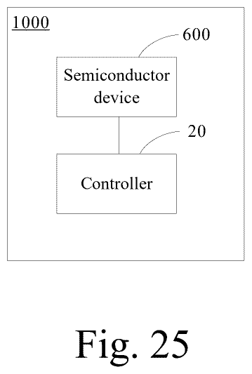

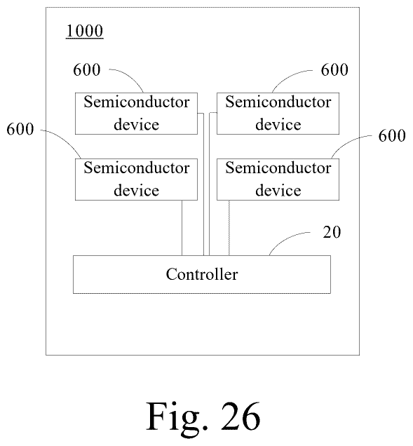

FIG. 25 is a block diagram of a memory system according to some implementations. FIG. 26 is a block diagram of a memory system according to some other implementations. Referring to FIGS. 25 and 26, some implementations of the present disclosure further provide a memory system 1000. The memory system 1000 includes a controller 20 and a semiconductor device 600 provided in the above implementations, where the controller 20 is coupled to the semiconductor device 600 to control the semiconductor device 600 to store data.

Where the memory system 1000 may be integrated into various types of memory devices, for example, be included in the same package (e.g. Universal Flash Storage (UFS) package or Embedded Multi Media Card (eMMC) package). That is to say, the memory system 1000 may be applied to and packaged into different types of electronic products, such as mobile phones (such as smartphones), desktop computers, tablets, laptops, servers, vehicle-mounted devices, game consoles, printers, positioning devices, wearable devices, smart sensors, mobile powers, virtual reality (VR) devices, augmented reality (AR) devices, or any other suitable electronic device having a memory therein.

In some implementations, referring to FIG. 25, the memory system 1000 includes a controller 20 and a semiconductor device 600, and the memory system 1000 may be integrated into a memory card. For example, the semiconductor device 600 may be a memory with a three-dimensional structure (3D NAND).

The memory card includes any one of PC card (PCMCIA, Personal Computer Memory Card International Association), Compact Flash (CF) card, Smart Media (SM) card, memory stick, Multimedia Card (MMC), Secure Digital Memory Card (SD device) card, UFS.

In some other implementations, referring to FIG. 26, the memory system 1000 includes a controller 20 and multiple semiconductor devices 600, and is integrated into a solid state drive (SSD device).

In memory system 1000, in some implementations, controller 20 is configured for operation in low duty cycle environments, such as SD device cards, CF cards, Universal Serial Bus (USB) flash drives, or other media used in electronic devices such as personal calculators, digital cameras, mobile phones, etc.

In some other implementations, the controller 20 is configured for operation in a high duty cycle environment SSD device or eMMC for data storage of mobile devices such as smart phones, tablets, laptops, and enterprise storage arrays.

In some implementations, the controller 20 may be configured to manage data stored in the semiconductor device 600 and communicate with external devices (such as a host). In some implementations, the controller 20 may also be configured to control the operations of the semiconductor device 600, such as read, erase, and program operations. In some implementations, the controller 20 may also be configured to manage various functions related to data stored or to be stored in the semiconductor device 600, including at least one of bad block management, garbage collection, logical to physical address translation, and loss balancing. In some implementations, the controller 20 is also configured to process error correction codes for data read from or written to the semiconductor device 600.

Of course, controller 20 may also perform any other suitable functions, such as formatting the semiconductor device 600. For example, controller 20 may communicate with external devices (such as a host) through at least one of various interface protocols.

It should be noted that the interface protocols include at least one of USB protocol, MMC protocol, Peripheral Component Interconnect (PCI) protocol, PCI Express (PCI-E) protocol, Advanced Technology Attachment (ATA) protocol, Serial ATA protocol, Parallel ATA protocol, Small Computer Small Interface (SCSI) protocol, Enhanced Small Disk Interface (ESD Device I) protocol, Integrated Drive Electronics (IDE) protocol, and Firewire protocol.

The controller 20 in the above implementations may be, for example, a Central Processing Unit (CPU), a general-purpose processor, a Digital Signal Processor (DSP), an Application Specific Integrated Circuit (ASIC), a Field Programmable Gate Array (FPGA), or other programmable logic devices, transistor logic devices, hardware components, or any combination thereof.

In this implementation, the memory system 1000 includes the semiconductor device 600 provided in some of the above implementations, which is beneficial to increasing the storage capacity of the memory system 1000 and improving the device performance of the memory system 1000 such as response speed.

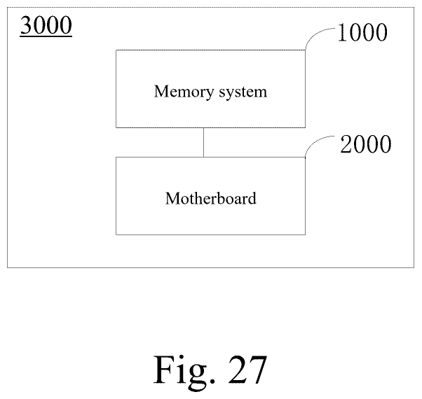

Some implementations of the present disclosure further provide an electronic device. FIG. 27 is a block diagram of an electronic device according to some implementations. As shown in FIG. 27, the electronic device 3000 includes a motherboard 2000 and the memory system 1000 provided by some of the above implementations, where the motherboard 2000 is electrically connected to the memory system 1000. In addition, the electronic device 3000 may also include at least one of a central processing unit (CPU) and a cache.

For example, the electronic device 3000 may be any of a mobile phone, desktop computer, tablet, laptop, server, vehicle-mounted device, wearable device (such as smartwatch, smart bracelet, smart glasses, etc.), mobile power, game console, digital multimedia player, etc.

In this implementation, the electronic device 3000 may include the memory system 1000 provided in some of the above implementations, which is beneficial to improving the storage density and capacity of the electronic device 3000, promoting the development of the electronic device 3000 towards a large capacity and small volume, and improving the device performance of the electronic device such as response speed.

The above is only specific implements of the present invention, but the scope of the present invention is not limited to this. Any variations or substitutions that may be easily conceived by those skilled in the art within the technical scope of the present invention should be included in the scope of the present invention. Therefore, the scope of the present invention should be determined according to the scope of the claims.

1. A semiconductor device, comprising:
a first stack structure, a source layer, and a second stack structure stacked sequentially along a first direction; and
a channel structure extending through the first stack structure, the source layer, and the second stack structure, and connected to the source layer.

2. The semiconductor device of claim 1, wherein:
the channel structure comprises a channel layer and a functional layer disposed around a portion of the channel layer;
the channel layer extends through the first stack structure, the source layer, and the second stack structure along the first direction; and
the functional layer comprises a first portion extending through the first stack structure and contacting the source layer, and a second portion extending through the second stack structure and contacting the source layer.

3. The semiconductor device of claim 1, wherein the first stack structure comprises a first sub-stack structure and a second sub-stack structure stacked along the first direction, and the second sub-stack structure is between the first sub-stack structure and the source layer.

4. The semiconductor device of claim 1, further comprising:
a first connection structure extending through the first stack structure, the source layer, and the second stack structure along the first direction, and connected to the source layer.

5. The semiconductor device of claim 4, further comprising a gate isolation structure, wherein the gate isolation structure extends through the first stack structure, the source layer, and the second stack structure along the first direction and is located on a side of the channel structure along a second direction, the second direction intersects with the first direction, and the first connection structure is disposed around the gate isolation structure.

6. The semiconductor device of claim 4, wherein:
the first stack structure comprises first gate layers and first dielectric layers stacked alternately along the first direction; and
the second stack structure comprises second gate layers and second dielectric layers stacked alternately along the first direction; and
the semiconductor device further comprises a first isolation layer between the first connection structure and the first gate layers, and a second isolation layer between the first connection structure and the second gate layers.

7. The semiconductor device of claim 1, wherein:
the first stack structure comprises first gate layers and first dielectric layers stacked alternately along the first direction;
the second stack structure comprises second gate layers and second dielectric layers stacked alternately along the first direction; and
the semiconductor device further comprises a second connection structure located on a side of the first stack structure and the second stack structure, wherein the second connection structure is connected to at least one of the first gate layers, and the second connection structure is connected to at least one of the second gate layers.

8. The semiconductor device of claim 7, wherein the second connection structure comprises:
a connection pillar extending along the first direction;
at least one of first connection layers, the first connection layers being parallel to a second direction, one of the first connection layers connecting the connection pillar and one of the first gate layers, the second direction intersecting with the first direction; and
at least one of second connection layers, the second connection layers being parallel to the second direction, one of the second connection layers connecting the connection pillar and one of the second gate layers.

9. The semiconductor device of claim 8, wherein the connection pillar, the first connection layers, and the second connection layers are in an integral structure.

10. The semiconductor device of claim 8, further comprising:
a third stack structure abutting the first stack structure along a third direction, and including third and fourth dielectric layers stacked alternately along the first direction, wherein the third direction intersects with the plane where the first and second directions are located; and
a fourth stack structure stacked with the third stack structure along the first direction, and including fifth and sixth dielectric layers stacked alternately along the first direction,
wherein the connection pillar extends through the third stack structure and the fourth stack structure, at least one of the third dielectric layers is connected to at least one of the first connection layers, and at least one of the fifth dielectric layers is connected to at least one of the second connection layers.

11. The semiconductor device of claim 10, wherein:
the source layer is between the third stack structure and the fourth stack structure, and the connection pillar extends through the source layer, and
the semiconductor device further comprises a third isolation layer disposed around the connection pillar and located between the connection pillar and the source layer.

12. The semiconductor device of claim 1, further comprising:
a first bit line extending in a direction intersecting with the first direction and located on a side of the first stack structure away from the second stack structure, the first bit line being connected to the channel structure; and
a second bit line extending in a direction intersecting with the first direction and located on a side of the second stack structure away from the first stack structure, the second bit line being connected to the channel structure,
wherein the first bit line is connected to the second bit line.

13. The semiconductor device of claim 12, further comprising a third connection structure extending through the first stack structure, the source layer, and the second stack structure, the third connection structure being connected to the first bit line, and to the second bit line.

14. A method of manufacturing a semiconductor device, comprising:
forming a first layer-stacked structure, wherein a first region of the first layer-stacked structure comprises multiple first sacrificial layers and multiple first dielectric layers stacked alternately along a first direction, and the first region of the first layer-stacked structure abuts a second region of the first layer-stacked structure;
forming a second sacrificial layer stacked with the first layer-stacked structure along the first direction;
forming a second layer-stacked structure located on a side of the second sacrificial layer away from the first layer-stacked structure, wherein a first region of the second layer-stacked structure includes multiple third sacrificial layers and multiple second dielectric layers stacked alternately along the first direction, and the first region of the second layer-stacked structure abuts a second region of the second layer-stacked structure;
forming a channel structure that extends through the first layer-stacked structure, the second sacrificial layer, and the second layer-stacked structure;
replacing the second sacrificial layer with a source layer, wherein the source layer is connected to the channel structure; and
replacing the first sacrificial layer with a first gate layer and replacing the third sacrificial layer with a second gate layer.

15. The method of claim 14, wherein:
after the forming the first layer-stacked structure and before the forming the second sacrificial layer, the method further comprises:
removing a portion of the first layer-stacked structure to form a first channel hole, wherein the first channel hole extends through the first region of the first layer-stacked structure; and
after the forming the second layer-stacked structure and before the forming the channel structure, the method further comprises:
removing a portion of the second layer-stacked structure and a portion of the second sacrificial layer to form a second channel hole, wherein the second channel hole extends through the first region of the second layer-stacked structure, and is in communication with the first channel hole, and the first and second channel holes collectively constitute a channel hole.

16. The method of claim 14, wherein:
the forming the first layer-stacked structure comprises:
forming a first sub-layer-stacked structure;
removing a portion of the first sub-layer-stacked structure to form a third channel hole that extends through a first region of the first sub-layer-stacked structure; and
forming a second sub-layer-stacked structure, wherein the second sub-layer-stacked structure is stacked with the first sub-layer-stacked structure along the first direction; and
the forming the second layer-stacked structure comprises:
forming a third sub-layer-stacked structure;
removing a portion of the second sub-layer-stacked structure, a portion of the second sacrificial layer, and a portion of the third sub-layer-stacked structure to form a fourth channel hole, wherein the fourth channel hole is in communication with the third channel hole;
forming a fourth sub-layer-stacked structure, wherein the fourth sub-layer-stacked structure is stacked with the third sub-layer-stacked structure along the first direction; and
removing a portion of the fourth sub-layer-stacked structure to form a fifth channel hole, wherein the fifth channel hole is in communication with the fourth channel hole, and the third, fourth, and fifth channel holes collectively constitute a channel hole.

17. The method of claim 15, wherein:
the forming the channel structure comprises:
forming a functional layer and a channel layer sequentially within the channel hole, wherein the functional layer is disposed around the channel layer; and
the replacing the second sacrificial layer with the source layer comprises:
removing a portion of the second sacrificial layer to form a first filling space, wherein the first filling space exposes a portion of the functional layer;
removing a portion of the functional layer by the first filling space, and dividing the functional layer into a first portion and a second portion, wherein the first portion extends through the first layer-stacked structure, and the second portion extends through the second layer-stacked structure; and
forming the source layer in the first filling space.

18. The method of claim 15, wherein the removing the portion of the layer-stacked structure to form the channel hole further comprising:
forming a gate line slit,
wherein the gate line slit is in the first region of the first layer-stacked structure and the first region of the second layer-stacked structure, and is located on a side of the channel hole along a second direction, and the second direction intersects with the first direction.

19. The method of claim 18, wherein the removing the portion of the second sacrificial layer to form the first filling space comprises:
removing the portion of the second sacrificial layer through the gate line slit.

20. The method of claim 18, wherein, after the replacing the first sacrificial layer with the first gate layer, the method further comprises:
forming an isolation layer, a first connection structure, and a gate isolation structure sequentially within the gate line slit, wherein the first connection structure is disposed around the gate isolation structure and is connected to the source layer, the isolation layer is disposed around the first connection structure, the isolation layer between the first connection structure and the first gate layer constitutes a first isolation layer, and the isolation layer between the first connection structure and the second gate layer constitutes a second isolation layer.
